(19) United States
(12) Patent Application Publication
(10) Pub. No.: US 2026/0173395 A1
(43) Pub. Date: Jun. 18, 2026

(54) SEMICONDUCTOR MEMORY DEVICE

(71) Applicant: Kioxia Corporation, Tokyo (JP)

(72) Inventors: Kiwamu SAKUMA, Yokkaichi (JP); Kunifumi SUZUKI, Yokkaichi (JP); Yasunao OTSUKI, Yokkaichi (JP)

(21) Appl. No.: 19/323,118

(22) Filed: Sep. 9, 2025

(30) Foreign Application Priority Data
Dec. 18, 2024 (JP) 2024-221977

(51) Int. Cl. H10B 51/30; H10B 51/20

(52) U.S. Cl. CPC H10B 51/30; H10B 51/20

(57) ABSTRACT

A semiconductor memory device includes: a semiconductor layer extending in a first direction; a first gate electrode layer; a second gate electrode layer provided spaced from the first gate electrode layer in the first direction; a gate insulating layer provided between the first gate electrode layer and the semiconductor layer, including hafnium (Hf) and oxygen (O), and including an orthorhombic or trigonal first crystal; and a metal silicide layer provided between the first gate electrode layer and the gate insulating layer.

### CROSS-REFERENCE TO RELATED APPLICATION

This application is based upon and claims the benefit of priority from Japanese Patent Application No. 2024-221977, filed Dec. 18, 2024, the entire contents of which are incorporated herein by reference.

### FIELD

Embodiments described herein relate generally to a semiconductor memory device.

### BACKGROUND

A ferroelectric memory attracts attention as a nonvolatile memory. For example, there is provided a ferroelectric FET (FeFET) three-terminal memory where a ferroelectric layer is applied to a gate insulating layer of a field effect transistor (FET) transistor to modulate a threshold voltage of the transistor. The threshold voltage of the transistor is modulated by changing a polarization state of the ferroelectric layer.

In a three-dimensional NAND flash memory where memory cells are three-dimensionally disposed, a high integration degree and a low cost are realized. In the three-dimensional NAND flash memory, for example, a memory hole that penetrates a stacked body where a plurality of insulating layers and a plurality of gate electrode layers are alternately stacked is formed in the stacked body. As the memory cell of the three-dimensional NAND flash memory, the FeFET three-terminal memory can be applied.

### DESCRIPTION OF THE DRAWINGS

FIG. 1 is a circuit diagram illustrating a memory cell array of a semiconductor memory device according to a first embodiment.

FIGS. 2A and 2B are schematic cross-sectional views illustrating the memory cell array of the semiconductor memory device according to the first embodiment.

FIG. 3 is a schematic cross-sectional view illustrating a memory cell of the semiconductor memory device according to the first embodiment.

FIG. 4 is a schematic cross-sectional view illustrating a method of manufacturing the semiconductor memory device according to the first embodiment.

FIG. 5 is a schematic cross-sectional view illustrating the method of manufacturing the semiconductor memory device according to the first embodiment.

FIG. 6 is a schematic cross-sectional view illustrating the method of manufacturing the semiconductor memory device according to the first embodiment.

FIG. 7 is a schematic cross-sectional view illustrating the method of manufacturing the semiconductor memory device according to the first embodiment.

FIG. 8 is a schematic cross-sectional view illustrating the method of manufacturing the semiconductor memory device according to the first embodiment.

FIG. 9 is a schematic cross-sectional view illustrating the method of manufacturing the semiconductor memory device according to the first embodiment.

FIG. 10 is a schematic cross-sectional view illustrating the method of manufacturing the semiconductor memory device according to the first embodiment.

FIG. 11 is a schematic cross-sectional view illustrating the method of manufacturing the semiconductor memory device according to the first embodiment.

FIG. 12 is a schematic cross-sectional view illustrating the method of manufacturing the semiconductor memory device according to the first embodiment.

FIG. 13 is a schematic cross-sectional view illustrating the method of manufacturing the semiconductor memory device according to the first embodiment.

FIGS. 14A and 14B are schematic cross-sectional views illustrating a memory cell array of a semiconductor memory device according to Comparative Example.

FIG. 15 is a schematic cross-sectional view illustrating a memory cell of the semiconductor memory device according to Comparative Example.

FIG. 16 is a schematic cross-sectional view illustrating a method of manufacturing the semiconductor memory device according to Comparative Example.

FIG. 17 is a schematic cross-sectional view illustrating the method of manufacturing the semiconductor memory device according to Comparative Example.

FIG. 18 is a schematic cross-sectional view illustrating the method of manufacturing the semiconductor memory device according to Comparative Example.

FIG. 19 is a schematic cross-sectional view illustrating the method of manufacturing the semiconductor memory device according to Comparative Example.

FIGS. 20A and 20B are schematic cross-sectional views illustrating a memory cell array of a semiconductor memory device according to a modification example of the first embodiment.

FIG. 21 is a schematic cross-sectional view illustrating a memory cell of the semiconductor memory device according to the modification example of the first embodiment.

FIGS. 22A and 22B are schematic cross-sectional views illustrating a memory cell array of a semiconductor memory device according to a second embodiment.

FIG. 23 is a schematic cross-sectional view illustrating a memory cell of the semiconductor memory device according to the second embodiment.

FIG. 24 is a schematic cross-sectional view illustrating a method of manufacturing the semiconductor memory device according to the second embodiment.

FIG. 25 is a schematic cross-sectional view illustrating the method of manufacturing the semiconductor memory device according to the second embodiment.

FIG. 26 is a schematic cross-sectional view illustrating the method of manufacturing the semiconductor memory device according to the second embodiment.

FIG. 27 is a schematic cross-sectional view illustrating the method of manufacturing the semiconductor memory device according to the second embodiment.

FIG. 28 is a schematic cross-sectional view illustrating the method of manufacturing the semiconductor memory device according to the second embodiment.

FIG. 29 is a schematic cross-sectional view illustrating the method of manufacturing the semiconductor memory device according to the second embodiment.

FIG. 30 is a schematic cross-sectional view illustrating the method of manufacturing the semiconductor memory device according to the second embodiment.

FIG. 31 is a schematic cross-sectional view illustrating the method of manufacturing the semiconductor memory device according to the second embodiment.

FIG. 32 is a schematic cross-sectional view illustrating the method of manufacturing the semiconductor memory device according to the second embodiment.

FIG. 33 is a schematic cross-sectional view illustrating the method of manufacturing the semiconductor memory device according to the second embodiment.

FIG. 34 is a schematic cross-sectional view illustrating the method of manufacturing the semiconductor memory device according to the second embodiment.

FIG. 35 is a circuit diagram illustrating a memory cell array of a semiconductor memory device according to a third embodiment.

FIGS. 36A and 36B are schematic cross-sectional views illustrating the memory cell array of the semiconductor memory device according to the third embodiment.

FIG. 37 is a schematic cross-sectional view illustrating the memory cell array of the semiconductor memory device according to the third embodiment.

FIG. 38 is a schematic cross-sectional view illustrating a memory cell of the semiconductor memory device according to the third embodiment.

FIG. 39 is a schematic cross-sectional view illustrating a method of manufacturing the semiconductor memory device according to the third embodiment.

FIG. 40 is a schematic cross-sectional view illustrating the method of manufacturing the semiconductor memory device according to the third embodiment.

FIG. 41 is a schematic cross-sectional view illustrating the method of manufacturing the semiconductor memory device according to the third embodiment.

FIG. 42 is a schematic cross-sectional view illustrating the method of manufacturing the semiconductor memory device according to the third embodiment.

FIG. 43 is a schematic cross-sectional view illustrating the method of manufacturing the semiconductor memory device according to the third embodiment.

FIG. 44 is a schematic cross-sectional view illustrating the method of manufacturing the semiconductor memory device according to the third embodiment.

FIG. 45 is a schematic cross-sectional view illustrating the method of manufacturing the semiconductor memory device according to the third embodiment.

FIG. 46 is a schematic cross-sectional view illustrating the method of manufacturing the semiconductor memory device according to the third embodiment.

FIG. 47 is a schematic cross-sectional view illustrating the method of manufacturing the semiconductor memory device according to the third embodiment.

FIG. 48 is a schematic cross-sectional view illustrating the method of manufacturing the semiconductor memory device according to the third embodiment.

FIG. 49 is a diagram illustrating an operation and effects of the semiconductor memory device according to the third embodiment.

### DETAILED DESCRIPTION

Embodiments provide a semiconductor memory device having excellent characteristics.

In general, according to one embodiment, a semiconductor memory device includes: a semiconductor layer extending in a first direction; a first gate electrode layer; a second gate electrode layer provided spaced from the first gate electrode layer in the first direction; a gate insulating layer provided between the first gate electrode layer and the semiconductor layer, including hafnium (Hf) and oxygen (O), and including an orthorhombic or trigonal first crystal; and a metal silicide layer provided between the first gate electrode layer and the gate insulating layer.

Hereinafter, embodiments will be described with reference to the drawings. In the following description, the same or similar members or the like will be represented by the same reference numerals, and description of members or the like described once will not be made appropriately in some cases.

In addition, for convenience of description, the term “up” or “down” may be used in the present specification. The term “up” or “down” merely represents a relative position relationship in the drawing and does not define a position relationship with respect to the gravity.

Qualitative analysis and quantitative analysis of chemical compositions of members forming a semiconductor memory device in the present specification can be performed, for example, by secondary ion mass spectroscopy (SIMS), energy dispersive X-ray spectroscopy (EDX), or electron energy loss spectroscopy (EELS). In addition, thicknesses of the members forming the semiconductor memory device, a distance between the members, and the like can be measured, for example, using a transmission electron microscope (TEM). In addition, identification of a crystal structure of a component of a member forming the semiconductor memory device, and determination of a magnitude relationship of an abundance of the crystal structure can be performed, for example, using a transmission electron microscope, X-ray diffraction (XRD), electron beam diffraction (EBD), X-ray photoelectron spectroscopy (XPS), or synchrotron radiation X-ray absorption fine structure (XAFS). Identification of a crystal structure of a component of a member forming the semiconductor memory device, and determination of a magnitude relationship of an abundance of the crystal structure can be performed, for example, by automated crystal orientation and phase mapping in TEM method (ACOM-TEM method) using a TEM.

“Ferroelectric” in the present specification refers to a substance where spontaneous polarization occurs without an electrical field being applied from an external apparatus, and polarization is reversed when an electrical field is applied from an external apparatus. In addition, “paraelectric” in the present specification refers to a substance where polarization occurs when an electrical field is applied, and polarization is disappeared when an electrical field is removed.

### First Embodiment

A semiconductor memory device according to a first embodiment includes: a semiconductor layer extending in a first direction; a first gate electrode layer; a second gate electrode layer provided to be isolated from the first gate electrode layer in the first direction; a gate insulating layer provided between the first gate electrode layer and the semiconductor layer, including hafnium (Hf) and oxygen (O), and including an orthorhombic or trigonal first crystal; and a metal silicide layer provided between the first gate electrode layer and the gate insulating layer.

The semiconductor memory device according to the first embodiment is a three-dimensional NAND flash memory including memory cells of a metal ferroelectrics semiconductor structure (MFS structure).

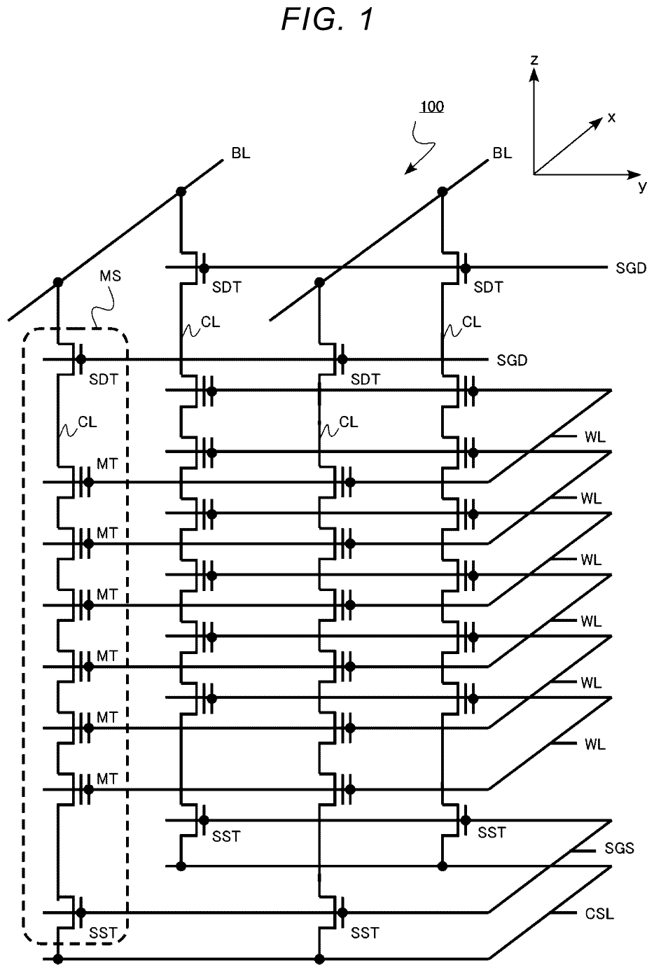

FIG. 1 is a circuit diagram illustrating a memory cell array of the semiconductor memory device according to the first embodiment.

As illustrated in FIG. 1, a memory cell array 100 of the three-dimensional NAND flash memory according to the first embodiment includes a plurality of word lines WL, a common source line CSL, a source select gate line SGS, a plurality of channel layers CL, a plurality of drain select gate lines SGD, a plurality of bit lines BL, and a plurality of memory strings MS.

A z direction in FIG. 1 is an example of the first direction. A y direction in FIG. 1 is an example of the second direction. A x direction in FIG. 1 is an example of the third direction. The first direction is a concept including the z direction and the opposite direction thereof. In addition, the second direction is a concept including the y direction and the opposite direction thereof. In addition, the third direction is a concept including the x direction and the opposite direction thereof.

The plurality of word lines WL are stacked in the z direction. The plurality of word lines WL are provided to be isolated in the z direction. The plurality of channel layers CL extend in the z direction. The plurality of bit lines BL extend in the x direction.

As illustrated in FIG. 1, the memory string MS is configured with a source select transistor SST, a plurality of memory cell transistors MT, and a drain select transistor SDT that are connected in series between the common source line CSL and the bit line BL. One memory string MS can be selected by the bit line BL and the drain select gate line SGD, and one memory cell transistor MT can be selected by the word line WL.

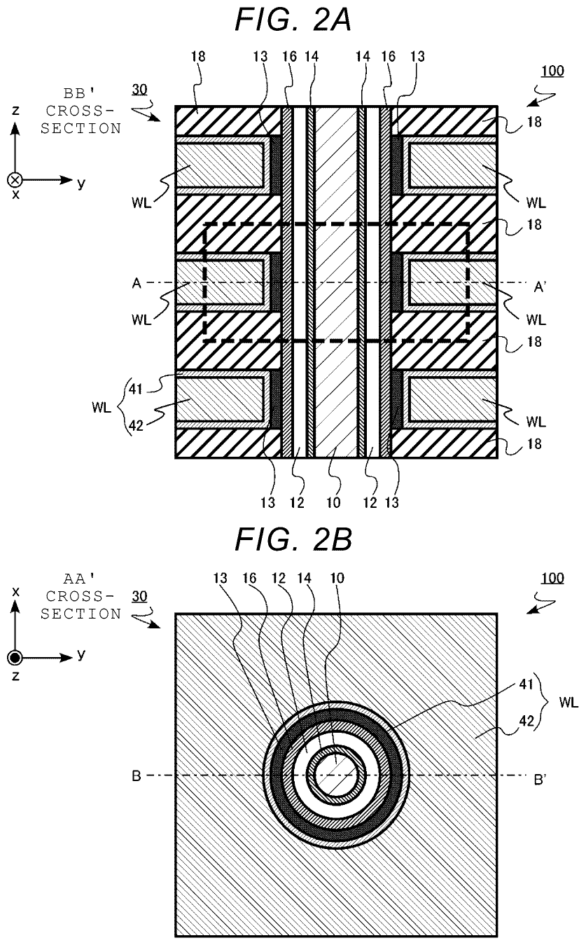

FIGS. 2A and 2B are schematic cross-sectional views illustrating the memory cell array of the semiconductor memory device according to the first embodiment. FIGS. 2A and 2B illustrate, for example, cross-sections of a plurality of memory cells of one memory string MS surrounded by dotted lines in the memory cell array 100 of FIG. 1.

FIG. 2A is a yz cross-sectional view of the memory cell array 100. FIG. 2A is a BB′ cross-section of FIG. 2B. FIG. 2B is a xy cross-sectional view of the memory cell array 100. FIG. 2B is an AA′ cross-section of FIG. 2A. In FIG. 2A, a region surrounded by a broken line is one memory cell.

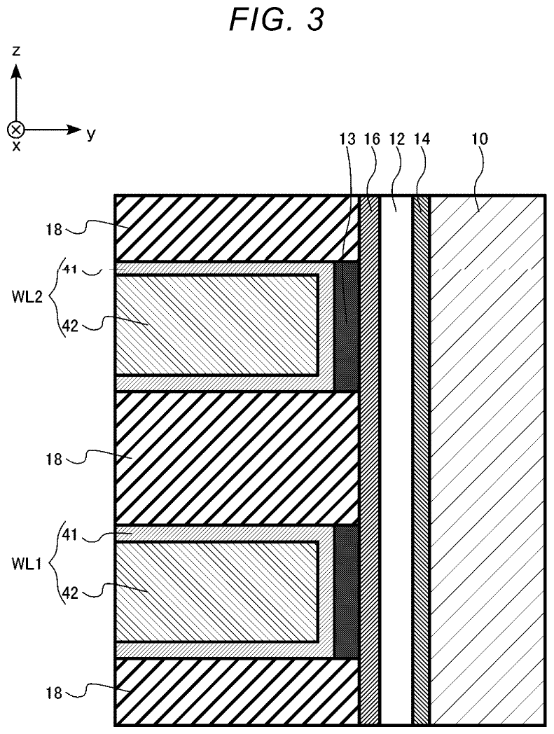

FIG. 3 is a schematic cross-sectional view illustrating memory cells of the semiconductor memory device according to the first embodiment. FIG. 3 is an enlarged cross-sectional view illustrating a part of two memory cells.

As illustrated in FIGS. 2A and 2B, the memory cell array 100 includes a plurality of word lines WL, a semiconductor layer 10, a gate insulating layer 12, a metal silicide layer 13, a first interface insulating layer 14, a second interface insulating layer 16, and a plurality of interlayer insulating layers 18. The plurality of word lines WL and the plurality of interlayer insulating layers 18 configure a stacked body 30. The word line WL includes a barrier metal film 41 and a metal region 42.

The interlayer insulating layers 18 is an example of the first insulating layer. The barrier metal film 41 is an example of the conductive film.

As illustrated in FIG. 3, two memory cells include a first word line WL1, a second word line WL2, the semiconductor layer 10, the gate insulating layer 12, the metal silicide layer 13, the first interface insulating layer 14, the second interface insulating layer 16, and the plurality of interlayer insulating layers 18.

The first word line WL1 is one of the plurality of word lines. The first word line WL1 is an example of the first gate electrode layer. The second word line WL2 is one of the plurality of word lines. The second word line WL2 is an example of the second gate electrode layer.

The word lines WL and the interlayer insulating layers 18 are provided on, for example, a semiconductor substrate (not illustrated). The word lines WL and the interlayer insulating layers 18 are provided in the z direction, for example, with respect to the semiconductor substrate (not illustrated).

The word lines WL and the interlayer insulating layers 18 are alternately stacked in the z direction on the semiconductor substrate. The word lines WL are disposed to be isolated in the z direction. For example, the second word line WL2 is provided to be isolated from the first word line WL1 in the z direction. The plurality of word lines WL and the plurality of interlayer insulating layers 18 configure the stacked body 30.

The word line WL is a plate-shaped conductor. The word line WL is, for example, a metal, a metal nitride, a metal carbide, or a semiconductor. The word line WL includes, for example, the barrier metal film 41 and the metal region 42. The barrier metal film 41 is provided between the metal region 42 and the gate insulating layer 12.

The barrier metal film 41 includes, for example, a metal, a metal nitride, or a metal carbide. The barrier metal film 41 includes, for example, titanium nitride, tungsten nitride, or tantalum nitride. The barrier metal film 41 is, for example, a titanium nitride film, a tungsten nitride film, or a tantalum nitride film.

The metal region 42 is a metal. The metal region 42 includes, for example, tungsten (W) or molybdenum (Mo). The metal region 42 is, for example, a tungsten layer or a molybdenum layer. The metal region 42 includes, for example, a different metal element from the barrier metal film 41.

The word line WL functions as a control electrode of the memory cell transistor MT.

A length of the word line WL in the z direction is, for example, 5 nm or more and 40 nm or less.

The interlayer insulating layer 18 separates the word line WL and the word line WL. The interlayer insulating layer 18 separates, for example, the first word line WL1 and the second word line WL2. The interlayer insulating layer 18 is, for example, an oxide, oxynitride, or nitride. The interlayer insulating layer 18 is, for example, silicon oxide.

A length of the interlayer insulating layers 18 in the z direction is, for example, 5 nm or more and 40 nm or less.

The semiconductor layer 10 is provided in the stacked body 30. The semiconductor layer 10 extends in the z direction. The semiconductor layer 10 is provided to penetrate the stacked body 30. The semiconductor layer 10 is, for example, columnar or cylindrical. The semiconductor layer 10 corresponds to the channel layers CL. For example, an insulating film may be provided inside the cylindrical semiconductor layer 10. The insulating film is, for example, silicon oxide.

The semiconductor layer 10 is, for example, a polycrystalline semiconductor. The semiconductor layer 10 is, for example, polycrystalline silicon. The semiconductor layer 10 functions as a channel of the memory cell transistor MT.

The gate insulating layer 12 is provided between the word line WL and the semiconductor layer 10. The gate insulating layer 12 is provided between the first word line WL1 and the semiconductor layer 10. The gate insulating layer 12 is provided between the second word line WL2 and the semiconductor layer 10.

The gate insulating layer 12 includes hafnium (Hf) and oxygen (O). For example, an atomic concentration of hafnium (Hf) is the highest among atomic concentrations of elements other than oxygen (O) in the gate insulating layer 12. A ratio of the atomic concentration of hafnium (Hf) to the sum of the atomic concentrations of the elements other than oxygen (O) in the gate insulating layer 12 is, for example, 90% or more.

The gate insulating layer 12 includes hafnium oxide. The gate insulating layer 12 includes, for example, hafnium oxide as a major component. The gate insulating layer 12 including hafnium oxide as a major component represents that a molar fraction of hafnium oxide is the highest among molar fractions of substances in the gate insulating layer 12. The molar fraction of hafnium oxide in the gate insulating layer 12 is, for example, 90% or higher.

The gate insulating layer 12 includes a ferroelectric. The gate insulating layer 12 is, for example, a ferroelectric layer.

The gate insulating layer 12 is crystalline. The gate insulating layer 12 includes an orthorhombic or trigonal first crystal. The first crystal is hafnium oxide. When hafnium oxide is an orthorhombic or trigonal crystal, the hafnium oxide has ferroelectricity. When hafnium oxide is an orthorhombic or trigonal crystal, the hafnium oxide is a ferroelectric. The first crystal is a ferroelectric.

When hafnium oxide is, for example, an orthorhombic III crystal (space group Pbc2₁, space group No. 29) or a trigonal crystal (space group R3m, P3, or R3, space group No. 160, 143, or 146), the hafnium oxide has ferroelectricity.

When hafnium oxide is a crystal other than an orthorhombic or trigonal crystal or is amorphous, the hafnium oxide does not have ferroelectricity. When hafnium oxide is a crystal other than an orthorhombic or trigonal crystal or is amorphous, the hafnium oxide is a paraelectric. The crystal other than an orthorhombic or trigonal crystal refers to a cubic, hexagonal, tetragonal, monoclinic, or triclinic crystal.

The gate insulating layer 12 includes, for example, cubic, hexagonal, tetragonal, monoclinic, or triclinic second crystal. The second crystal is a paraelectric.

The gate insulating layer 12 includes, for example, the orthorhombic or trigonal first crystal as a main component. Including the orthorhombic or trigonal first crystal as a main component refers to that the orthorhombic or trigonal first crystal has the highest abundance among substances forming the gate insulating layer 12. In other words, Including the orthorhombic or trigonal first crystal as a main component means that there is no substance having a higher abundance than the orthorhombic or trigonal first crystal among the substances forming the gate insulating layer 12. For example, an abundance of the first crystal in the ferroelectric is higher than that of the second crystal in the paraelectric among the substances forming the gate insulating layer 12. In addition, for example, the abundance of the first crystal in the ferroelectric is the highest among the crystals forming the gate insulating layer 12.

The gate insulating layer 12 includes, for example, a ferroelectric as a main component. The abundance of the ferroelectric in the gate insulating layer 12 is higher than, for example, the abundance of the paraelectric in the gate insulating layer 12.

The gate insulating layer 12 includes, for example, at least one addition element selected from the group consisting of silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Ru). Hafnium oxide in the gate insulating layer 12 includes the addition element. For example, hafnium oxide includes the addition element such that the hafnium oxide is likely to exhibit ferroelectricity.

The first interface insulating layer 14 is provided between the first word line WL1 and the semiconductor layer 10. The first interface insulating layer 14 is provided between the second word line WL2 and the semiconductor layer 10. The first interface insulating layer 14 is provided between the gate insulating layer 12 and the semiconductor layer 10.

A material of the first interface insulating layer 14 is different from, for example, a material of the gate insulating layer 12. The first interface insulating layer 14 is, for example, an oxide, oxynitride, or nitride. The first interface insulating layer 14 is, for example, silicon oxide.

By removing the first interface insulating layer 14, a structure where the gate insulating layer 12 is in direct contact with the semiconductor layer 10 can also be adopted.

The second interface insulating layer 16 is provided between the first word line WL1 and the gate insulating layer 12. The second interface insulating layer 16 is provided between the second word line WL2 and the gate insulating layer 12. The second interface insulating layer 16 is provided between the metal silicide layer 13 and the gate insulating layer 12.

A material of the second interface insulating layer 16 is different from, for example, the material of the gate insulating layer 12. The second interface insulating layer 16 is, for example, an oxide, oxynitride, or nitride. The second interface insulating layer 16 is, for example, silicon oxide or aluminum oxide.

A structure where the second interface insulating layer 16 is not provided and the gate insulating layer 12 is in direct contact with the metal silicide layer 13 can also be adopted.

The metal silicide layer 13 is provided between the first word line WL1 and the gate insulating layer 12. The metal silicide layer 13 is provided between the second word line WL2 and the gate insulating layer 12. The metal silicide layer 13 is provided between the first word line WL1 and the second interface insulating layer 16. The metal silicide layer 13 is provided between the second word line WL2 and the second interface insulating layer 16.

The metal silicide layer 13 is in contact with, for example, the first word line WL1. The metal silicide layer 13 is in contact with, for example, the second word line WL2. The metal silicide layer 13 is in contact with, for example, the second interface insulating layer 16.

The metal silicide layers 13 is separated in the z direction. The metal silicide layer 13 provided between the first word line WL1 and the gate insulating layer 12 and the metal silicide layer 13 provided between the second word line WL2 and the gate insulating layer 12 are isolated in the z direction. The interlayer insulating layers 18 is provided between the metal silicide layer 13 provided between the first word line WL1 and the gate insulating layer 12 and the metal silicide layer 13 provided between the second word line WL2 and the gate insulating layer 12.

The metal silicide layer 13 is not provided between the interlayer insulating layers 18 and the semiconductor layer 10 in the y direction. The metal silicide layer 13 is not provided between the interlayer insulating layers 18 and the gate insulating layer 12 in the y direction. The metal silicide layer 13 is not provided between the interlayer insulating layers 18 and the second interface insulating layer 16 in the y direction. The metal silicide layer 13 is in contact with, for example, the interlayer insulating layers 18 in the z direction.

The metal silicide layer 13 surrounds the gate insulating layer 12 in a cross-section perpendicular to the z direction. The metal silicide layer 13 surrounds the semiconductor layer 10 in the cross-section perpendicular to the z direction.

The metal silicide layer 13 includes a metal silicide. The metal silicide layer 13 includes silicon (Si) and a metal element. The metal element is, for example, titanium (Ti) or tungsten (W). The metal silicide layer 13 includes, for example, titanium silicide or tungsten silicide. The metal silicide layer 13 is, for example, a titanium silicide layer or a tungsten silicide layer.

In the memory cell according to the first embodiment, for example, a polarization reversal state of the ferroelectric in the gate insulating layer 12 is controlled by a voltage to be applied between the first word line WL1 and the semiconductor layer 10. A threshold voltage of the memory cell transistor MT changes depending on the polarization reversal state of the gate insulating layer 12. By changing the threshold voltage of the memory cell transistor MT, an ON current of the memory cell transistor MT changes. For example, when a state where the threshold voltage is high and the ON current is low is defined by data of “0” and a state where the threshold voltage is low and the ON current is high is defined by data of “1”, the memory cell can store one-bit data of “0” and “1”.

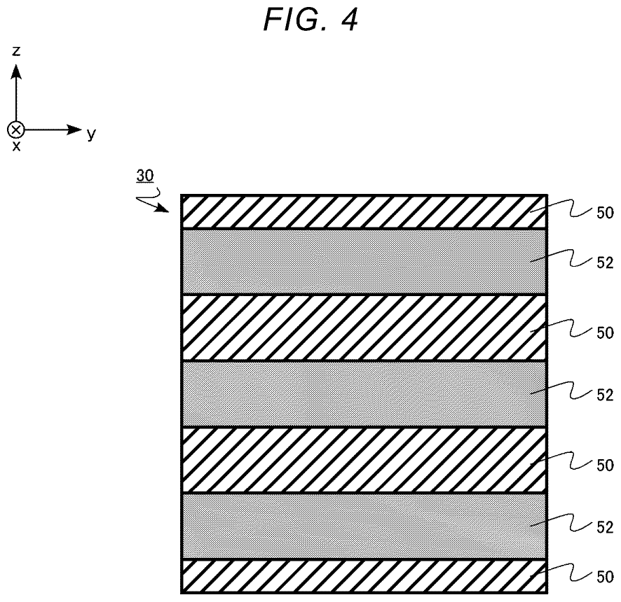

Next, an example of a method of manufacturing the semiconductor memory device according to the first embodiment will be described. FIGS. 4, 5, 6, 7, 8, 9, 10, 11, 12, and 13 are schematic cross-sectional views illustrating the method of manufacturing the semiconductor memory device according to the first embodiment. Each of FIGS. 4 to 13 illustrates cross-sections corresponding to FIG. 2A. FIGS. 4 to 13 illustrate the example of the method of manufacturing the memory cell array 100 of the semiconductor memory device.

First, a silicon oxide layer 50 and a polycrystalline silicon layer 52 are alternately stacked on a semiconductor substrate (not illustrated) (FIG. 4). The stacked body 30 is formed with the silicon oxide layer 50 and the polycrystalline silicon layer 52. The silicon oxide layer 50 and the polycrystalline silicon layer 52 are formed, for example, using a chemical vapor deposition method (CVD method). A part of the silicon oxide layer 50 is finally the interlayer insulating layers 18.

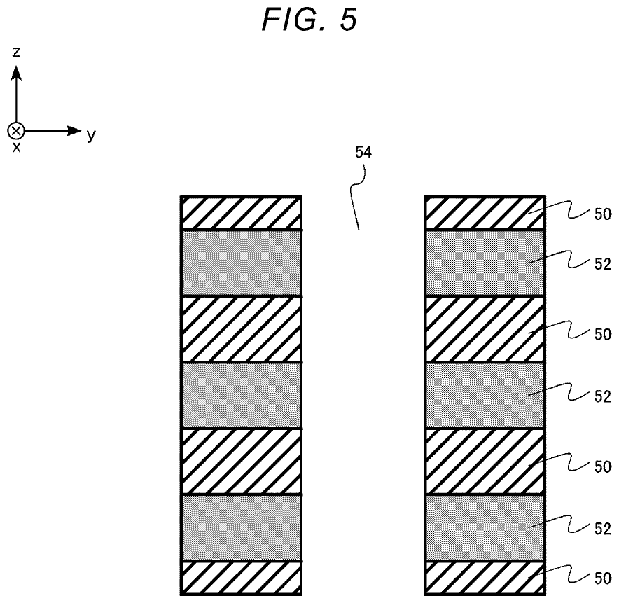

Next, an opening 54 is formed in the silicon oxide layer 50 and the polycrystalline silicon layer 52 (FIG. 5). The opening 54 is formed, for example, using a lithography method and a reactive ion etching method (RIE method).

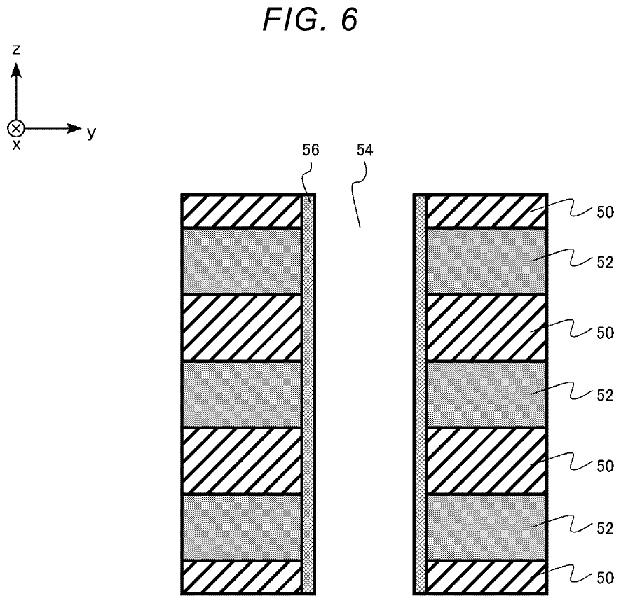

Next, a titanium film 56 is formed in the opening 54 (FIG. 6). The titanium film 56 is formed, for example, using a CVD method.

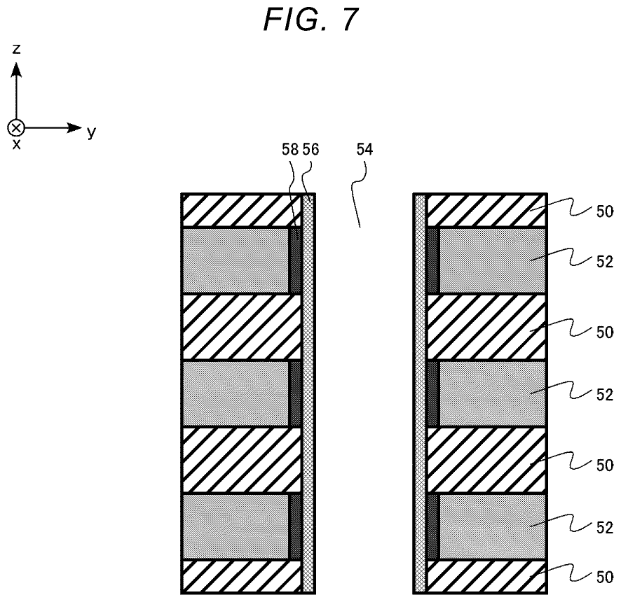

Next, by performing a heat treatment such that the polycrystalline silicon layer 52 reacts with the titanium film 56, a titanium silicide layer 58 is formed (FIG. 7). The heat treatment is performed, for example, in an inert gas atmosphere at a temperature of 600° C. or higher and 800° C. or lower. The titanium silicide layer 58 is finally the metal silicide layer 13.

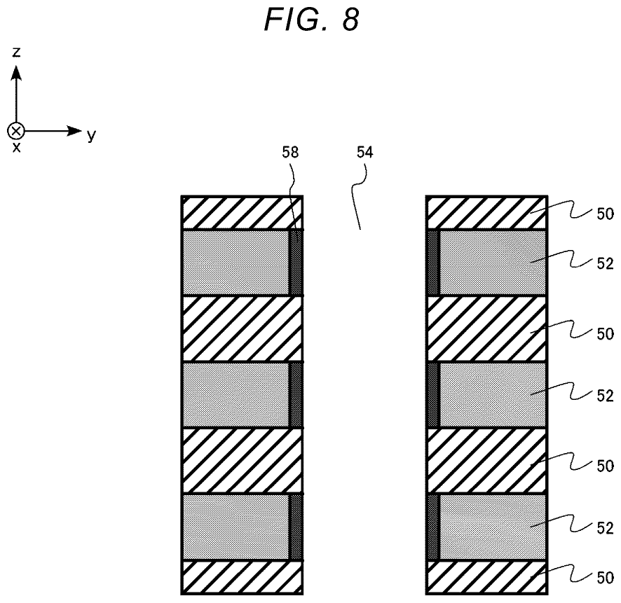

Next, the unreacted titanium film 56 is removed (FIG. 8). The titanium film 56 is removed, for example, using a wet etching method.

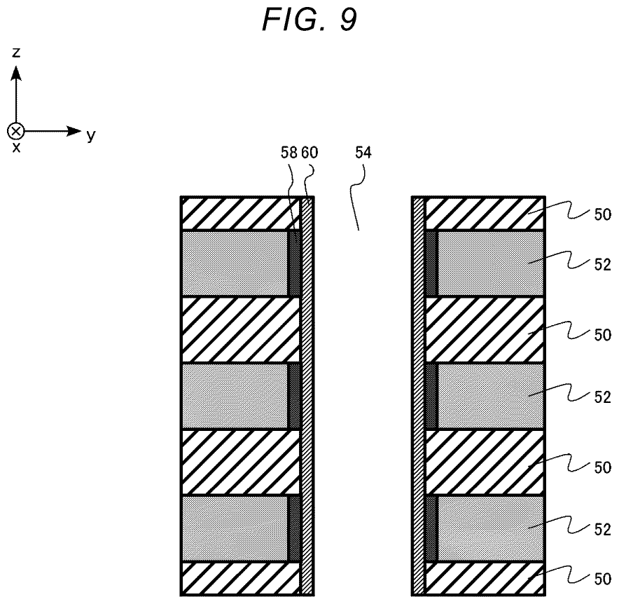

Next, a first silicon oxide film 60 is formed in the opening 54 (FIG. 9). The first silicon oxide film 60 is formed, for example, using a CVD method. The first silicon oxide film 60 is finally the second interface insulating layer 16.

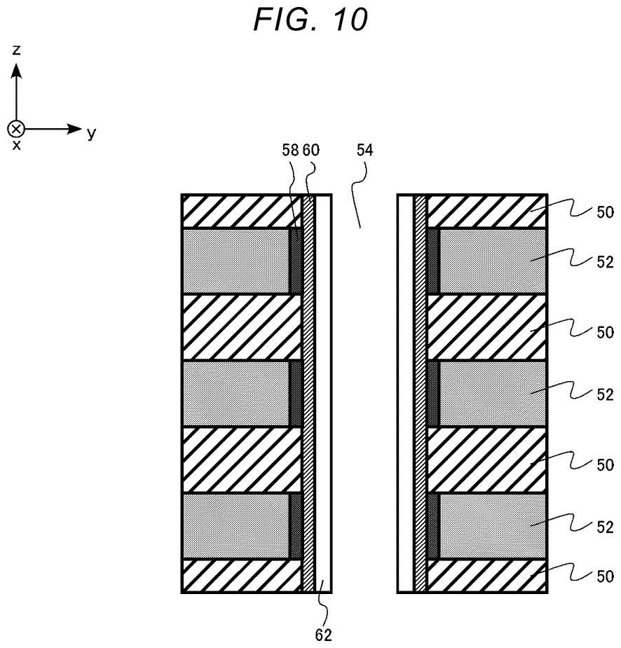

Next, a hafnium oxide film 62 is formed in the opening 54 (FIG. 10). The hafnium oxide film 62 is formed, for example, using an atomic layer deposition method (ALD method). For example, silicon (Si) as an addition element is added to the hafnium oxide film 62. The hafnium oxide film 62 is finally the gate insulating layer 12.

Next, a second silicon oxide film 64 is formed on an inner surface of the opening 54. The second silicon oxide film 64 is formed, for example, using a CVD method. The second silicon oxide film 64 is finally the first interface insulating layer 14.

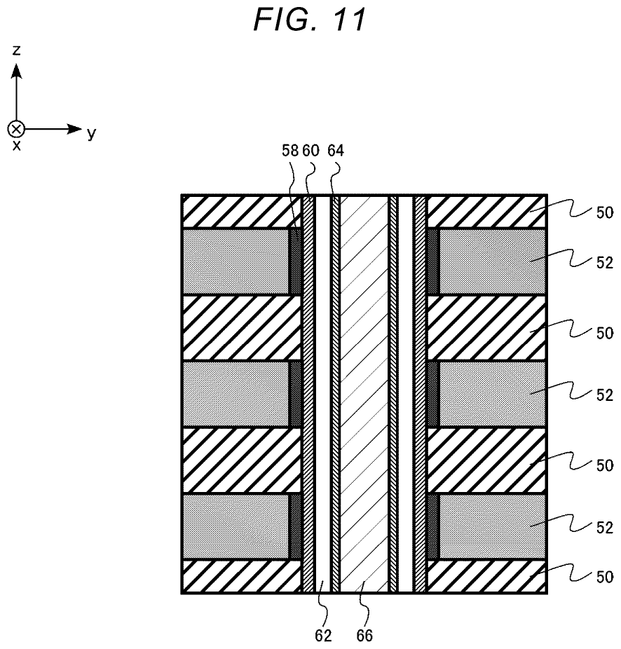

Next, a polycrystalline silicon film 66 is formed in the opening 54 to fill the opening 54 (FIG. 11). The polycrystalline silicon film 66 is formed, for example, using a CVD method. The polycrystalline silicon film 66 is finally the semiconductor layer 10.

Next, by performing a heat treatment, the hafnium oxide film 62 is crystallized. The heat treatment is so-called crystallized annealing. By crystallizing the hafnium oxide film 62, an orthorhombic or trigonal first crystal is formed in the hafnium oxide film 62. The heat treatment is performed, for example, in an inert gas atmosphere at a temperature of 800° C. or higher and 1000° C. or lower.

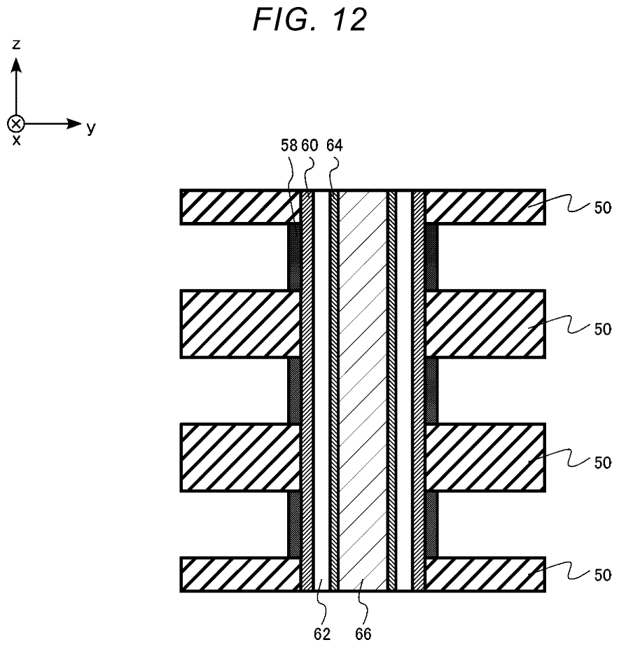

Next, using a groove for etching (not illustrated), the polycrystalline silicon layer 52 is selectively removed by a wet etching method (FIG. 12).

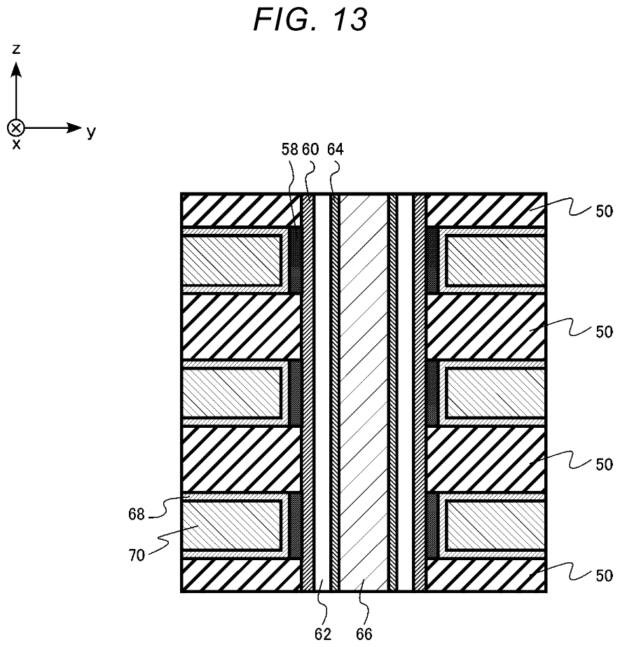

Next, a titanium nitride film 68 and a tungsten film 70 are formed on the titanium silicide layer 58 (FIG. 13). The titanium nitride film 68 and the tungsten film 70 are formed, for example, using a CVD method. The titanium nitride film 68 and the tungsten film 70 are finally word lines WL. The titanium nitride film 68 is finally the barrier metal film 41. The tungsten film 70 is finally the metal region 42.

The heat treatment for crystallizing the hafnium oxide film 62 can also be performed, for example, immediately after forming the second silicon oxide film 64. The heat treatment for crystallizing the hafnium oxide film 62 is performed, for example, before the removal of the polycrystalline silicon layer 52 after the formation of the second silicon oxide film 64.

Through the above-described manufacturing method, the semiconductor memory device according to the first embodiment is manufactured.

Next, the operation and effects of the semiconductor memory device according to the first embodiment will be described.

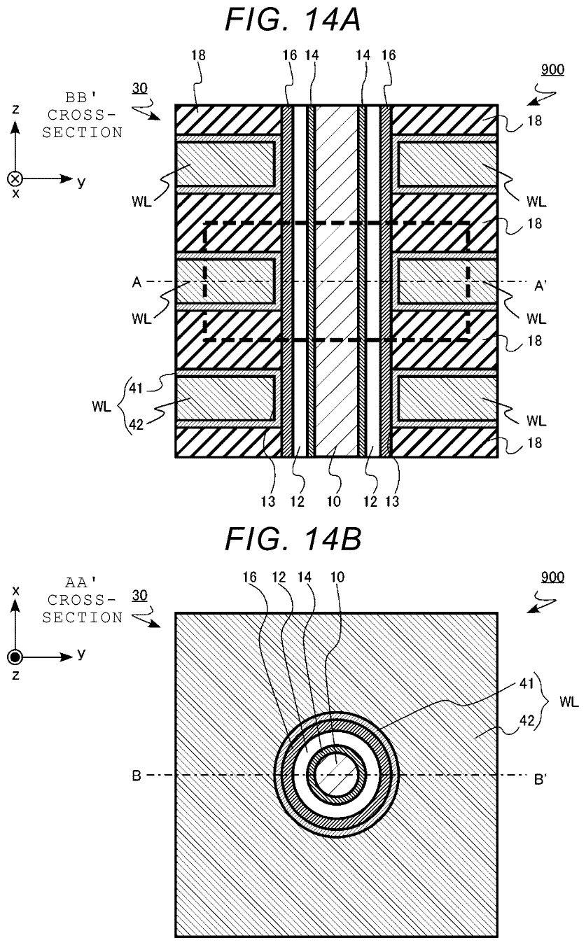

FIGS. 14A and 14B are schematic cross-sectional views illustrating a memory cell array of a semiconductor memory device according to Comparative Example. FIG. 14A is a yz cross-sectional view of a memory cell array 900 according to Comparative Example. FIG. 14A is a BB′ cross-section of FIG. 14B. FIG. 14B is a xy cross-sectional view of the memory cell array 900. FIG. 14B is an AA′ cross-section of FIG. 14A. In FIG. 14A, a region surrounded by a broken line is one memory cell. FIGS. 14A and 14B are diagrams corresponding to FIGS. 2A and 2B of the first embodiment.

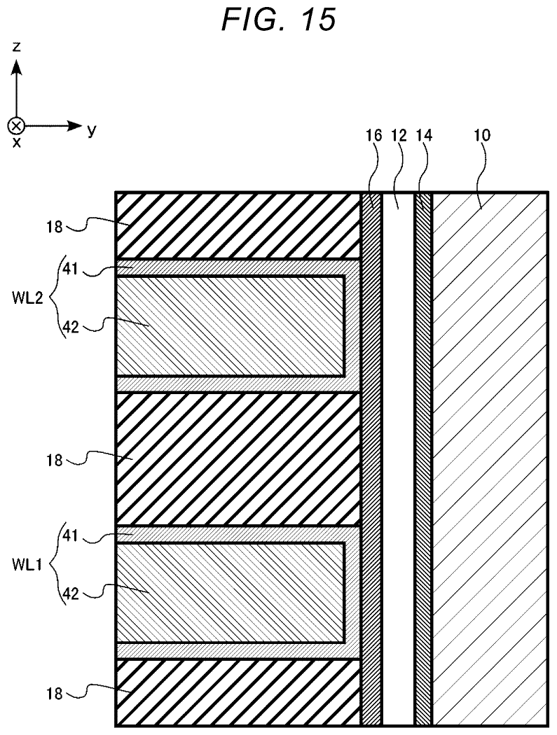

FIG. 15 is a schematic cross-sectional view illustrating the memory cell of the semiconductor memory device according to Comparative Example. FIG. 15 is an enlarged cross-sectional view illustrating a part of two memory cells. FIG. 15 is a diagram corresponding to FIG. 3 of the first embodiment.

The memory cell of the semiconductor memory device according to Comparative Example is different from the memory cell of the semiconductor memory device according to the first embodiment, in that the metal silicide layer 13 is not provided between the first word line WL1 and the gate insulating layer 12 and between the second word line WL2 and the gate insulating layer 12.

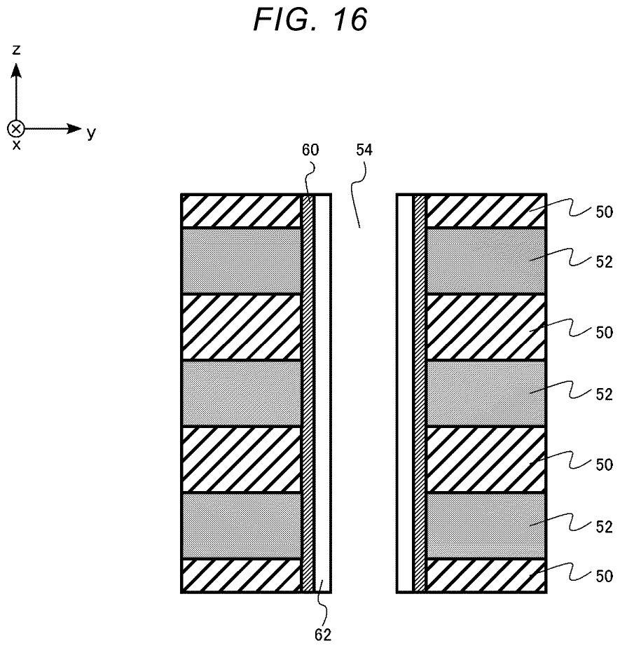

Next, a method of manufacturing the semiconductor memory device according to Comparative Example will be described. FIGS. 16, 17, 18, and 19 are schematic cross-sectional views illustrating the method of manufacturing the semiconductor memory device according to Comparative Example. Each of FIGS. 16 to 19 illustrates cross-sections corresponding to FIG. 14A. FIGS. 16 to 19 illustrate the example of the method of manufacturing the memory cell array 900 of the semiconductor memory device according to Comparative Example.

The method of manufacturing the semiconductor memory device according to Comparative Example is the same as the method of manufacturing the semiconductor memory device according to the first embodiment until the opening 54 is formed in the silicon oxide layer 50 and the polycrystalline silicon layer 52.

Next, the first silicon oxide film 60 is formed in the opening 54. The first silicon oxide film 60 is formed, for example, using a CVD method. The first silicon oxide film 60 is finally the second interface insulating layer 16.

Next, the hafnium oxide film 62 is formed in the opening 54 (FIG. 16). The hafnium oxide film 62 is formed, for example, using an ALD method. For example, silicon (Si) as an addition element is added to the hafnium oxide film 62. The hafnium oxide film 62 is finally the gate insulating layer 12.

Next, the second silicon oxide film 64 is formed on an inner surface of the opening 54. The second silicon oxide film 64 is formed, for example, using a CVD method. The second silicon oxide film 64 is finally the first interface insulating layer 14.

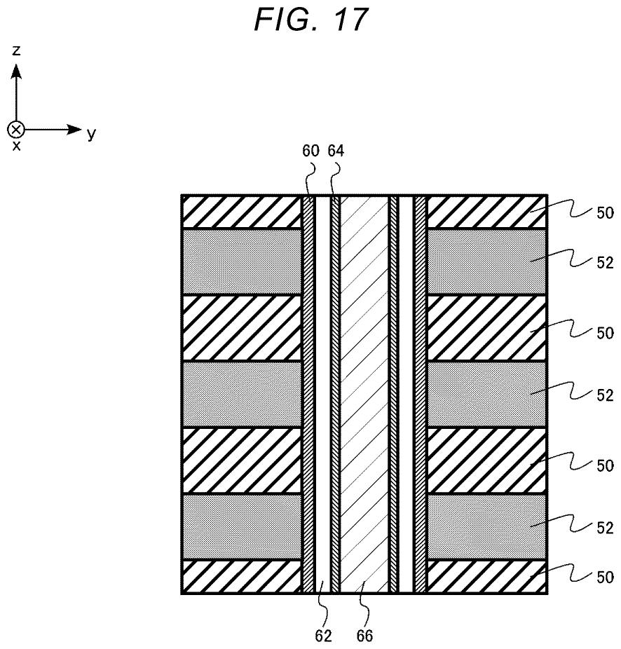

Next, the polycrystalline silicon film 66 is formed in the opening 54 to fill the opening 54 (FIG. 17). The polycrystalline silicon film 66 is formed, for example, using a CVD method. The polycrystalline silicon film 66 is finally the semiconductor layer 10.

Next, by performing a heat treatment, the hafnium oxide film 62 is crystallized. The heat treatment is so-called crystallized annealing. By crystallizing the hafnium oxide film 62, an orthorhombic or trigonal first crystal is formed in the hafnium oxide film 62. The heat treatment is performed, for example, in an inert gas atmosphere at a temperature of 800° C. or higher and 1000° C. or lower.

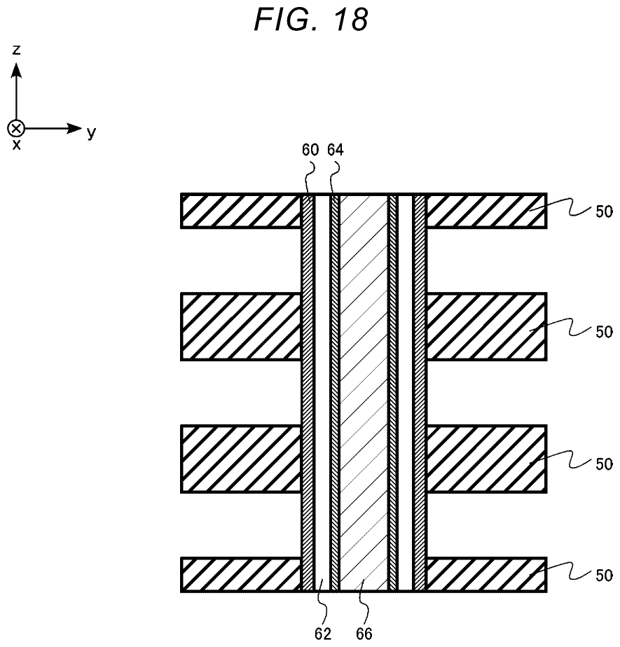

Next, using a groove for etching (not illustrated), the polycrystalline silicon layer 52 is selectively removed by wet etching (FIG. 18).

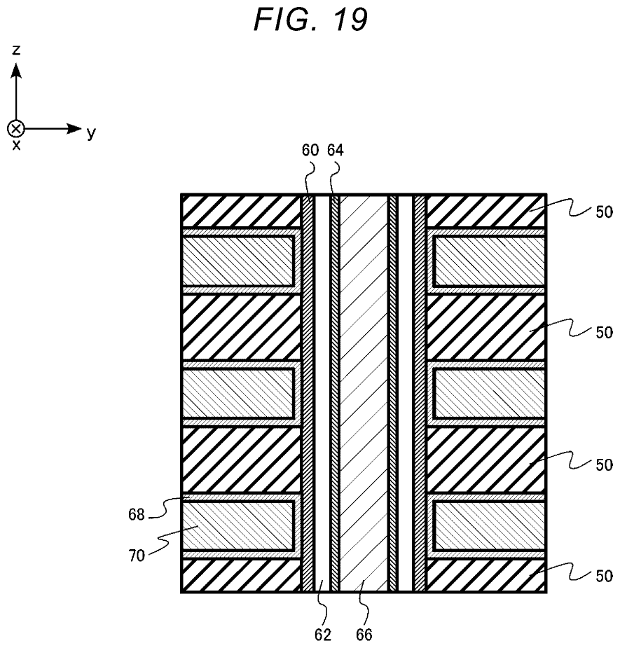

Next, the titanium nitride film 68 and the tungsten film 70 are formed on the first silicon oxide film 60 (FIG. 19). The titanium nitride film 68 and the tungsten film 70 are formed, for example, using a CVD method. The titanium nitride film 68 and the tungsten film 70 are finally word lines WL. The titanium nitride film 68 is finally the barrier metal film 41. The tungsten film 70 is finally the metal region 42.

Through the above-described manufacturing method, the semiconductor memory device according to Comparative Example is manufactured.

The method of manufacturing the semiconductor memory device according to Comparative Example is different from the method of manufacturing the semiconductor memory device according to the first embodiment, in that the formation of the titanium silicide layer 58 is not performed.

In the method of manufacturing the semiconductor memory device according to Comparative Example, by performing crystallized annealing on the hafnium oxide film 62, the hafnium oxide film 62 is crystallized. By crystallizing the hafnium oxide film 62, an orthorhombic or trigonal first crystal is formed in the hafnium oxide film 62. In other words, a ferroelectric is formed in the hafnium oxide film 62.

When crystallized annealing is performed, the hafnium oxide film 62 is interposed between the polycrystalline silicon layer 52 and the polycrystalline silicon film 66. By performing crystallized annealing in a state where the hafnium oxide film 62 is interposed between the polycrystalline silicon layer 52 and the polycrystalline silicon film 66, the formation of the ferroelectric in the hafnium oxide film 62 is promoted. It is considered that the formation of the ferroelectric in the hafnium oxide film 62 is promoted by stress applied from the polycrystalline silicon layer 52 and the polycrystalline silicon film 66 to the hafnium oxide film 62.

In the method of manufacturing the semiconductor memory device according to Comparative Example, the polycrystalline silicon layer 52 is removed after crystallized annealing, and subsequently the titanium nitride film 68 and the tungsten film 70 are formed. It was clarified from an investigation of the present inventors that, when the polycrystalline silicon layer 52 is removed after crystallized annealing, the ferroelectric formed in the hafnium oxide film 62 decreases.

The reason for this is considered to be that, by removing the polycrystalline silicon layer 52, stress applied to the hafnium oxide film 62 decreases such that the metastable orthorhombic or trigonal first crystal is transformed into the stable cubic, hexagonal, tetragonal, monoclinic, or triclinic second crystal. In other words, it is considered that the ferroelectric first crystal is transformed into the paraelectric second crystal.

In the semiconductor memory device according to Comparative Example, the ferroelectricity of the gate insulating layer 12 is weakened by reducing the abundance of the ferroelectric in the gate insulating layer 12. In the semiconductor memory device according to Comparative Example, by weakening the ferroelectricity of the gate insulating layer 12, for example, the write endurance of the memory cell deteriorates. Accordingly, for example, the reliability of the semiconductor memory device according to Comparative Example decreases. Accordingly, the characteristics of the semiconductor memory device according to Comparative Example deteriorate.

The semiconductor memory device according to the first embodiment includes the metal silicide layer 13 between the word line WL and the gate insulating layer 12. In the method of manufacturing the semiconductor memory device according to the first embodiment, when crystallized annealing is performed, the hafnium oxide film 62 is interposed between the titanium silicide layer 58 that is finally the metal silicide layer 13 and the polycrystalline silicon film 66. By performing crystallized annealing in a state where the hafnium oxide film 62 is interposed between the titanium silicide layer 58 and the polycrystalline silicon film 66, the formation of the ferroelectric in the hafnium oxide film 62 is promoted.

In particular, when the hafnium oxide film 62 is interposed between the titanium silicide layer 58 and the polycrystalline silicon film 66, the formation of the ferroelectric in the hafnium oxide film 62 is further promoted as compared to Comparative Example. The reason for this is considered to be that, when the hafnium oxide film 62 is interposed between the titanium silicide layer 58 and the polycrystalline silicon film 66, stress applied to the hafnium oxide film 62 increases as compared to when the hafnium oxide film 62 is interposed between the polycrystalline silicon layer 52 and the polycrystalline silicon film 66.

In the method of manufacturing the semiconductor memory device according to the first embodiment, as in Comparative Example, the polycrystalline silicon layer 52 is removed after crystallized annealing, and subsequently the titanium nitride film 68 and the tungsten film 70 are formed. However, unlike Comparative Example, the titanium silicide layer 58 remains even after removing the polycrystalline silicon layer 52. Therefore, a decrease of stress applied to the hafnium oxide film 62 after removing the polycrystalline silicon layer 52 is reduced, and a decrease in the ferroelectric formed in the hafnium oxide film 62 is reduced. Accordingly, by increasing the ferroelectricity of the gate insulating layer 12, deterioration in the write endurance of the memory cell is reduced. For example, the reliability of the semiconductor memory device according to the first embodiment is improved. Accordingly, the characteristics of the semiconductor memory device according to the first embodiment are improved.

### Modification Example

A semiconductor memory device according to a modification example of the first embodiment is different from the semiconductor memory device according to the first embodiment, in that the gate insulating layer is not provided between the first insulating layer and the semiconductor layer.

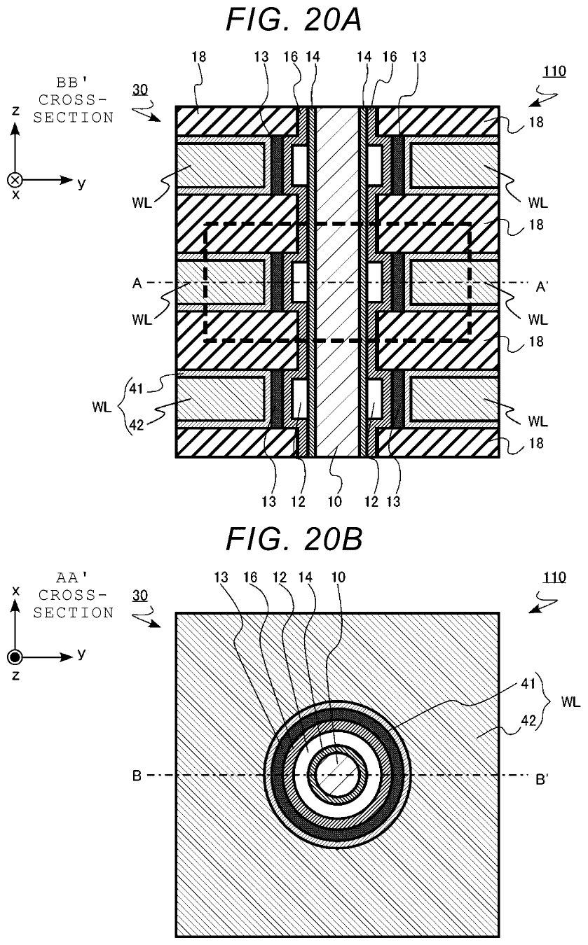

FIGS. 20A and 20B are schematic cross-sectional views illustrating a memory cell array of the semiconductor memory device according to the modification example of the first embodiment. FIG. 20A is a yz cross-sectional view of a memory cell array 110 according to the modification example. FIG. 20A is a BB′ cross-section of FIG. 20B. FIG. 20B is a xy cross-sectional view of the memory cell array 110. FIG. 20B is an AA′ cross-section of FIG. 20A. In FIG. 20A, a region surrounded by a broken line is one memory cell. FIGS. 20A and 20B are diagrams corresponding to FIGS. 2A and 2B of the first embodiment.

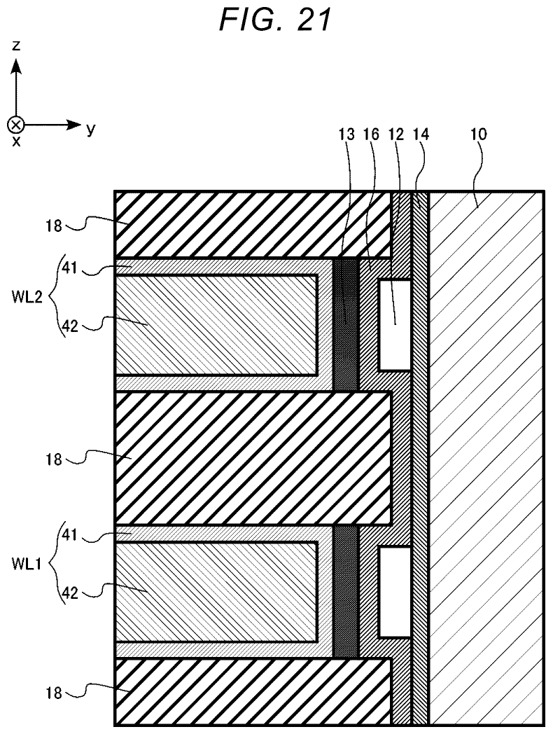

FIG. 21 is a schematic cross-sectional view illustrating the memory cell of the semiconductor memory device according to the modification example of the first embodiment. FIG. 21 is an enlarged cross-sectional view illustrating a part of two memory cells. FIG. 21 is a diagram corresponding to FIG. 3 of the first embodiment.

The memory cell according to the modification example of the first embodiment is different from the memory cell of the semiconductor memory device according to the first embodiment, in that the gate insulating layer 12 is not provided between the interlayer insulating layers 18 and the semiconductor layer 10.

In the semiconductor memory device according to the modification example of the first embodiment, as in the first embodiment, by providing the metal silicide layer 13, deterioration in the write endurance of the memory cell is reduced, and for example, the reliability of the semiconductor memory device according to the modification example of the first embodiment is improved. Accordingly, the characteristics of the semiconductor memory device according to the modification example of the first embodiment are improved.

In addition, in the semiconductor memory device according to the modification example of the first embodiment, the gate insulating layer 12 is not provided between the interlayer insulating layers 18 and the semiconductor layer 10. As a result, as compared to when the gate insulating layer 12 is provided between the interlayer insulating layers 18 and the semiconductor layer 10, for example, read characteristics of data of the memory cell are stable. The reason for this is considered to be that the read characteristics of data of the memory cell is not affected by the polarization state of the gate insulating layer 12 between the interlayer insulating layers 18 and the semiconductor layer 10.

From the above, in the semiconductor memory device according to the first embodiment and the modification example, the memory cell includes the metal silicide layer 13 such that the ferroelectricity of the gate insulating layer 12 is increased. Accordingly, the semiconductor memory device having excellent characteristics can be implemented.

### Second Embodiment

A semiconductor memory device according to a second embodiment includes: a semiconductor layer extending in a first direction; a first gate electrode layer; a second gate electrode layer provided to be isolated from the first gate electrode layer in the first direction; a first insulating layer provided between the first gate electrode layer and the second gate electrode layer; a gate insulating layer provided between the first gate electrode layer and the semiconductor layer, including hafnium (Hf) and oxygen (O), and including an orthorhombic or trigonal first crystal; and a metal layer provided between the first gate electrode layer and the gate insulating layer. The gate insulating layer is not provided between the first insulating layer and the semiconductor layer in a second direction perpendicular to the first direction, and a first thickness in the second direction of both end portions of the metal layer in the first direction is more than a second thickness in the second direction of an intermediate portion of the metal layer in the first direction. A semiconductor memory device according to a second embodiment is different from the semiconductor memory device according to the first embodiment, in that the metal layer is provided instead of the metal silicide layer, and the first thickness in the second direction of both of the end portions of the metal layer in the first direction is more than the second thickness in the second direction of the intermediate portion of the metal layer in the first direction. Hereinafter, the description of a part of the same contents as those of the first embodiment will not be repeated.

The semiconductor memory device according to the second embodiment is a three-dimensional NAND flash memory including memory cells of the MFS structure.

The semiconductor memory device according to the second embodiment has the same circuit configuration as that of the memory cell array of the semiconductor memory device according to the first embodiment illustrated in FIG. 1.

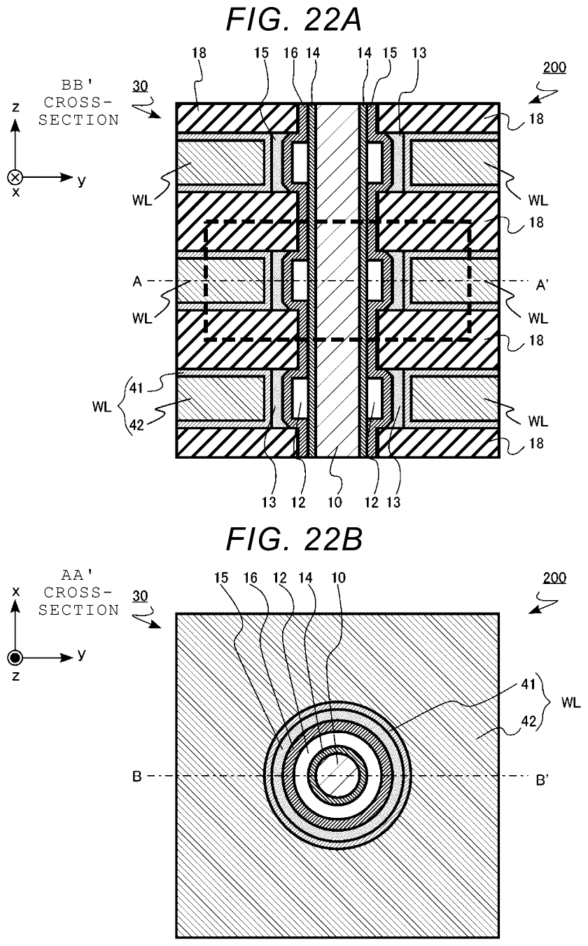

FIGS. 22A and 22B are schematic cross-sectional views illustrating the memory cell array of the semiconductor memory device according to the second embodiment. FIGS. 22A and 22B illustrate a cross-section of a plurality of memory cells in a memory cell array 200.

FIG. 22A is a yz cross-sectional view of the memory cell array 200. FIG. 22A is a BB′ cross-section of FIG. 22B. FIG. 22B is a xy cross-sectional view of the memory cell array 200. FIG. 22B is an AA′ cross-section of FIG. 22A. In FIG. 22A, a region surrounded by a broken line is one memory cell.

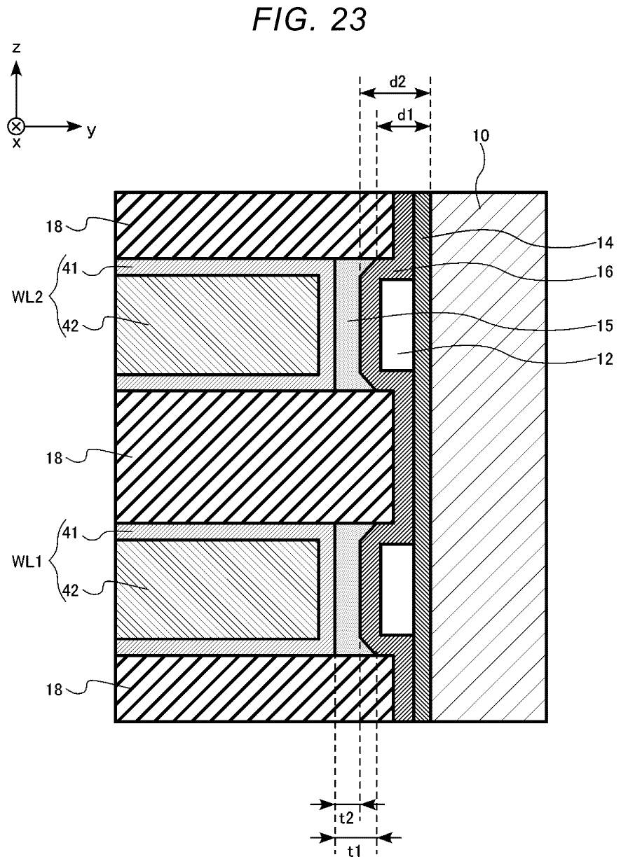

FIG. 23 is a schematic cross-sectional view illustrating memory cells of the semiconductor memory device according to the second embodiment. FIG. 23 is an enlarged cross-sectional view illustrating a part of two memory cells.

As illustrated in FIGS. 22A and 22B, the memory cell array 200 includes the plurality of word lines WL, the semiconductor layer 10, the gate insulating layer 12, the first interface insulating layer 14, a metal layer 15, the second interface insulating layer 16, and the plurality of interlayer insulating layers 18. The plurality of word lines WL and the plurality of interlayer insulating layers 18 configure the stacked body 30. The word line WL includes the barrier metal film 41 and the metal region 42.

The interlayer insulating layers 18 is an example of the first insulating layer. The barrier metal film 41 is an example of the conductive film.

As illustrated in FIG. 23, two memory cells include the first word line WL1, the second word line WL2, the semiconductor layer 10, the gate insulating layer 12, the first interface insulating layer 14, the metal layer 15, the second interface insulating layer 16, and the plurality of interlayer insulating layers 18.

The gate insulating layer 12 is provided between the word line WL and the semiconductor layer 10. The gate insulating layer 12 is provided between the first word line WL1 and the semiconductor layer 10. The gate insulating layer 12 is provided between the second word line WL2 and the semiconductor layer 10. The gate insulating layer 12 is provided, for example, between the second interface insulating layer 16 and the first interface insulating layer 14.

The gate insulating layer 12 is not provided between the interlayer insulating layers 18 and the semiconductor layer 10 in the y direction. The gate insulating layer 12 is not provided between the second interface insulating layer 16 and the first interface insulating layer 14 in the y direction.

The gate insulating layer 12 is separated in the z direction. The gate insulating layer 12 provided between the first word line WL1 and the semiconductor layer 10 and the gate insulating layer 12 provided between the second word line WL2 and the semiconductor layer 10 are isolated in the z direction. The second interface insulating layer 16 is provided between the gate insulating layer 12 provided between the first word line WL1 and the semiconductor layer 10 and the gate insulating layer 12 provided between the second word line WL2 and the semiconductor layer 10.

The gate insulating layer 12 includes hafnium (Hf) and oxygen (O). An atomic concentration of hafnium (Hf) is the highest among atomic concentrations of elements other than oxygen (O) in the gate insulating layer 12. A ratio of the atomic concentration of hafnium (Hf) to the sum of the atomic concentrations of the elements other than oxygen (O) in the gate insulating layer 12 is, for example, 90% or more.

The gate insulating layer 12 includes hafnium oxide. The gate insulating layer 12 includes, for example, hafnium oxide as a major component. The gate insulating layer 12 including hafnium oxide as a major component represents that a molar fraction of hafnium oxide is the highest among molar fractions of substances in the gate insulating layer 12. The molar fraction of hafnium oxide in the gate insulating layer 12 is, for example, 90% or higher.

The gate insulating layer 12 includes a ferroelectric. The gate insulating layer 12 is, for example, a ferroelectric layer. The gate insulating layer 12 is crystalline.

The gate insulating layer 12 includes an orthorhombic or trigonal first crystal. The first crystal is hafnium oxide. When hafnium oxide is an orthorhombic or trigonal crystal, the hafnium oxide has ferroelectricity. When hafnium oxide is an orthorhombic or trigonal crystal, the hafnium oxide is a ferroelectric. Accordingly, the first crystal is a ferroelectric.

When hafnium oxide is, for example, an orthorhombic III crystal (space group Pbc2₁, space group No. 29) or a trigonal crystal (space group R3m, P3, or R3, space group No. 160, 143, or 146), the hafnium oxide has ferroelectricity.

When hafnium oxide is a crystal other than an orthorhombic or trigonal crystal or is amorphous, the hafnium oxide does not have ferroelectricity. When hafnium oxide is a crystal other than an orthorhombic or trigonal crystal or is amorphous, the hafnium oxide is a paraelectric. The crystal other than an orthorhombic or trigonal crystal refers to a cubic, hexagonal, tetragonal, monoclinic, or triclinic crystal.

The gate insulating layer 12 includes, for example, cubic, hexagonal, tetragonal, monoclinic, or triclinic second crystal. The second crystal is a paraelectric.

The gate insulating layer 12 includes, for example, the orthorhombic or trigonal first crystal as a main component. Including the orthorhombic or trigonal first crystal as a main component refers to that the orthorhombic or trigonal first crystal has the highest abundance among substances forming the gate insulating layer 12. In other words, including orthorhombic or trigonal first crystal as a main component means that there is no substance having a higher abundance than the orthorhombic or trigonal first crystal among the substances forming the gate insulating layer 12. For example, an abundance of the first crystal in the ferroelectric is higher than that of the second crystal in the paraelectric among the substances forming the gate insulating layer 12. In other words, for example, the abundance of the first crystal in the ferroelectric is the highest among the crystals forming the gate insulating layer 12.

The gate insulating layer 12 includes, for example, a ferroelectric as a main component. The abundance of the ferroelectric in the gate insulating layer 12 is higher than, for example, the abundance of the paraelectric in the gate insulating layer 12.

The gate insulating layer 12 includes, for example, at least one addition element selected from the group consisting of silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Ru). Hafnium oxide in the gate insulating layer 12 includes the addition element. For example, hafnium oxide includes the addition element such that the hafnium oxide is likely to exhibit ferroelectricity.

The first interface insulating layer 14 is provided between the first word line WL1 and the semiconductor layer 10. The first interface insulating layer 14 is provided between the second word line WL2 and the semiconductor layer 10. The first interface insulating layer 14 is provided between the gate insulating layer 12 and the semiconductor layer 10.

The second interface insulating layer 16 is provided between the first word line WL1 and the gate insulating layer 12. The second interface insulating layer 16 is provided between the second word line WL2 and the gate insulating layer 12. The second interface insulating layer 16 is provided between the metal layer 15 and the gate insulating layer 12.

The metal layer 15 is provided between the first word line WL1 and the gate insulating layer 12. The metal layer 15 is provided between the second word line WL2 and the gate insulating layer 12. The metal layer 15 is provided between the first word line WL1 and the second interface insulating layer 16. The metal layer 15 is provided between the second word line WL2 and the second interface insulating layer 16.

The metal layer 15 is in contact with, for example, the first word line WL1. The metal layer 15 is in contact with, for example, the second word line WL2. The metal layer 15 is in contact with, for example, the second interface insulating layer 16.

The metal layer 15 is separated in the z direction. The metal layer 15 provided between the first word line WL1 and the gate insulating layer 12 and the metal layer 15 provided between the second word line WL2 and the gate insulating layer 12 are isolated in the z direction. The interlayer insulating layers 18 is provided between the metal layer 15 provided between the first word line WL1 and the gate insulating layer 12 and the metal layer 15 provided between the second word line WL2 and the gate insulating layer 12.

The metal layer 15 is not provided between the interlayer insulating layers 18 and the semiconductor layer 10 in the y direction. The metal layer 15 is not provided between the interlayer insulating layers 18 and the gate insulating layer 12 in the y direction. The metal layer 15 is not provided between the interlayer insulating layers 18 and the second interface insulating layer 16 in the y direction. The metal layer 15 is in contact with, for example, the interlayer insulating layers 18 in the z direction.

The metal layer 15 is not provided between the first word line WL1 and the interlayer insulating layers 18 in the z direction. The metal layer 15 is not provided between the second word line WL2 and the interlayer insulating layers 18 in the z direction. In the z direction, the first word line WL1 and the interlayer insulating layers 18 are in contact with each other. In the z direction, the second word line WL2 and the interlayer insulating layers 18 are in contact with each other.

A first thickness (t1 in FIG. 23) in the y direction perpendicular to the z direction of both end portions of the metal layer 15 in the z direction is more than a second thickness (t2 in FIG. 23) in the y direction of an intermediate portion of the metal layer 15 in the z direction. For example, the first thickness t1 is 1.1 times or more and 3 times or less the second thickness t2.

A first distance (d1 in FIG. 23) in the y direction between both of the end portions of the metal layer 15 in the z direction and the semiconductor layer 10 is smaller than a second distance (d2 in FIG. 23) in the y direction between the intermediate portion of the metal layer 15 in the z direction and the semiconductor layer 10. The first distance d1 is, for example, 10% or more and 90% or less of the second distance d2.

A length of the metal layer 15 in the z direction is more than a length of the gate insulating layer 12 in the z direction.

The metal layer 15 surrounds the gate insulating layer 12 in a cross-section perpendicular to the z direction. The metal layer 15 surrounds the semiconductor layer 10 in a cross-section perpendicular to the z direction.

The metal layer 15 includes a metal element. The metal layer 15 includes, for example, a metal, a metal nitride, a metal carbide, or a metal semiconductor compound. The metal layer 15 includes, for example, titanium (Ti), tungsten (W), or tantalum (Ta). The metal layer 15 includes, for example, titanium, tungsten, titanium nitride, tungsten nitride, tantalum nitride, titanium silicide, or tungsten silicide. The metal layer 15 is, for example, a titanium layer, a tungsten layer, a titanium nitride layer, a tungsten nitride layer, a tantalum nitride layer, a titanium silicide layer, or a tungsten silicide layer.

For example, a material of the metal layer 15 is different from a material of the word line WL. For example, the material of the metal layer 15 is different from a material of the barrier metal film 41. For example, the material of the metal layer 15 is different from a material of the metal region 42.

For example, a chemical composition of the metal layer 15 is different from a chemical composition of the word line WL. For example, the chemical composition of the metal layer 15 is different from a chemical composition of the barrier metal film 41. For example, the chemical composition of the metal layer 15 is different from a chemical composition of the metal region 42. For example, the word line WL includes a metal element different from the metal layer 15.

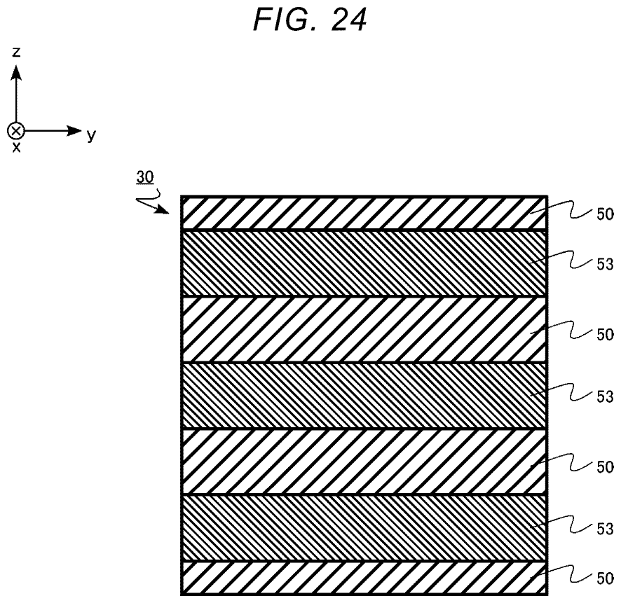

Next, an example of a method of manufacturing the semiconductor memory device according to the second embodiment will be described. FIGS. 24, 25, 26, 27, 28, 29, 30, 31, 32, 33, and 34 are schematic cross-sectional views illustrating the method of manufacturing the semiconductor memory device according to the second embodiment. Each of FIGS. 24 to 34 illustrates cross-sections corresponding to FIG. 22A. FIGS. 24 to 34 illustrate the example of the method of manufacturing the memory cell array 200 of the semiconductor memory device.

First, the silicon oxide layer 50 and a silicon nitride layer 53 are alternately stacked on a semiconductor substrate (not illustrated) (FIG. 24). The stacked body 30 is formed with the silicon oxide layer 50 and the silicon nitride layer 53. The silicon oxide layer 50 and the silicon nitride layer 53 are formed, for example, using a CVD method. A part of the silicon oxide layer 50 is finally the interlayer insulating layers 18.

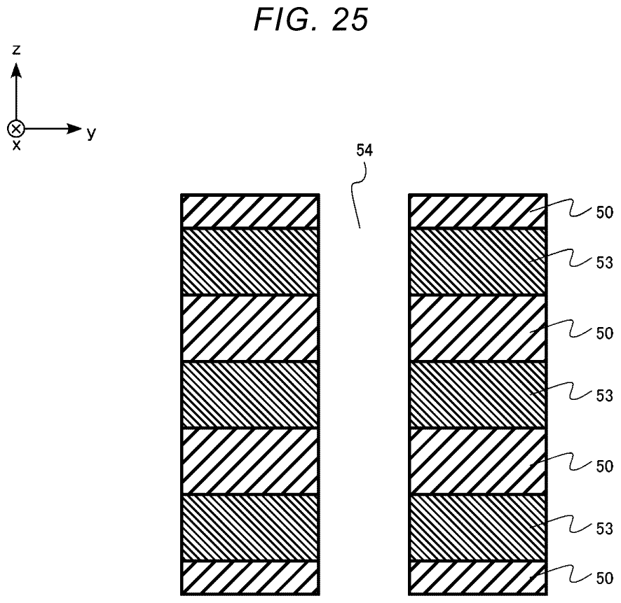

Next, the opening 54 is formed in the silicon oxide layer 50 and the silicon nitride layer 53 (FIG. 25). The opening 54 is formed, for example, using a lithography method and a RIE method.

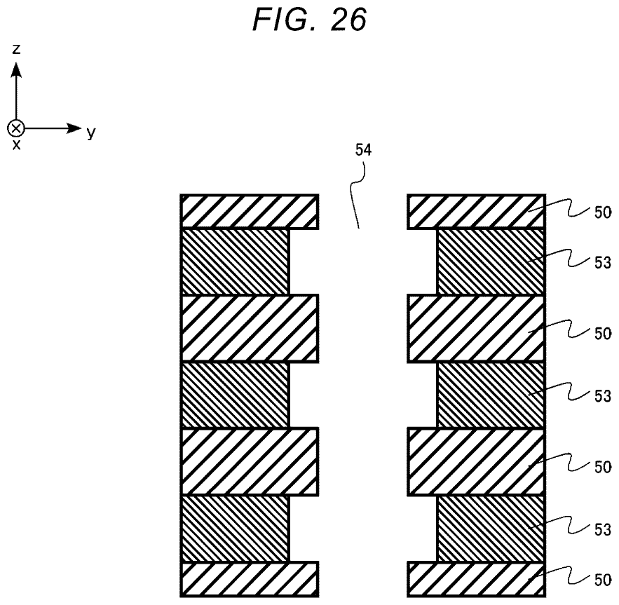

Next, the silicon nitride layer 53 exposed to the inner surface of the opening 54 is selectively retracted by wet etching (FIG. 26). During the wet etching, for example, the silicon nitride layer 53 is selectively etched relative to the silicon oxide layer 50 using a phosphoric acid solution. The silicon nitride layer 53 on the inner surface of the opening 54 is retracted to form a recess portion.

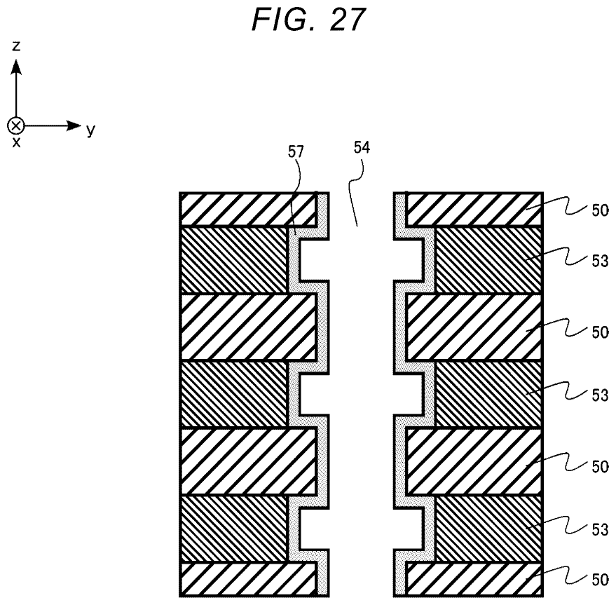

Next, a first titanium nitride film 57 is formed in the opening 54 (FIG. 27). The first titanium nitride film 57 is formed, for example, using a CVD method. The first titanium nitride film 57 is formed on the inner surface of the opening 54 and an upper surface, a side surface, and a lower surface of the recess portion of the opening 54.

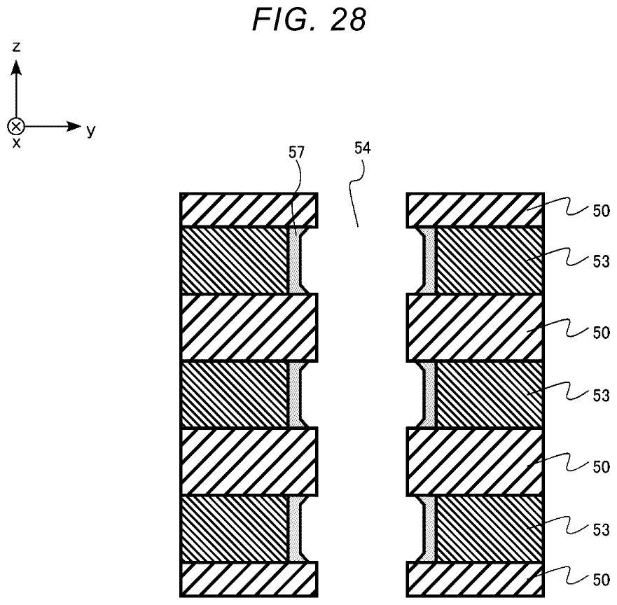

Next, the first titanium nitride film 57 of the inner surface of the opening 54 is removed by etching (FIG. 28). The first titanium nitride film 57 is removed using a RIE method or a wet etching method.

A part of the first titanium nitride film 57 remains in the recess portion formed by retracting the silicon nitride layer 53. The etching is controlled such that a thickness in the y direction of both end portions of the first titanium nitride film 57 of the recess portion in the z direction is more than a thickness in the y direction of an intermediate portion of the first titanium nitride film 57 of the recess portion in the z direction.

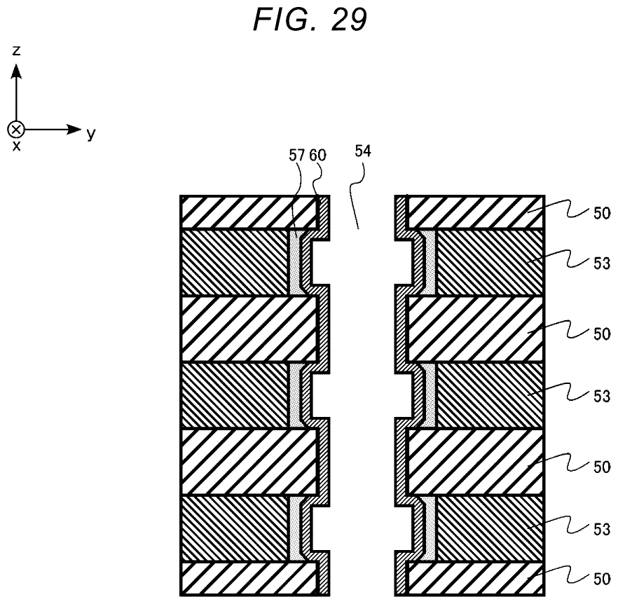

Next, the first silicon oxide film 60 is formed in the opening 54 (FIG. 29). The first silicon oxide film 60 is formed, for example, using a CVD method. The first silicon oxide film 60 is finally the second interface insulating layer 16.

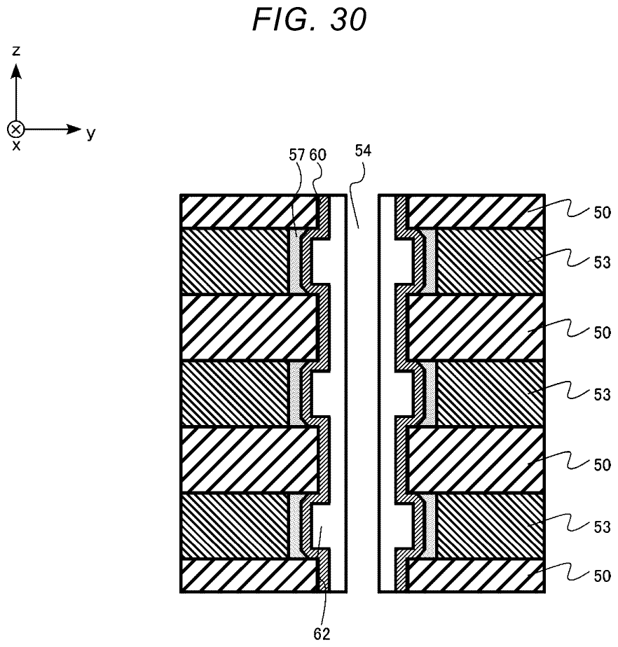

Next, the hafnium oxide film 62 is formed in the opening 54 (FIG. 30). The hafnium oxide film 62 is formed, for example, using an ALD method. For example, silicon (Si) as an addition element is added to the hafnium oxide film 62. A part of the hafnium oxide film 62 is finally the gate insulating layer 12.

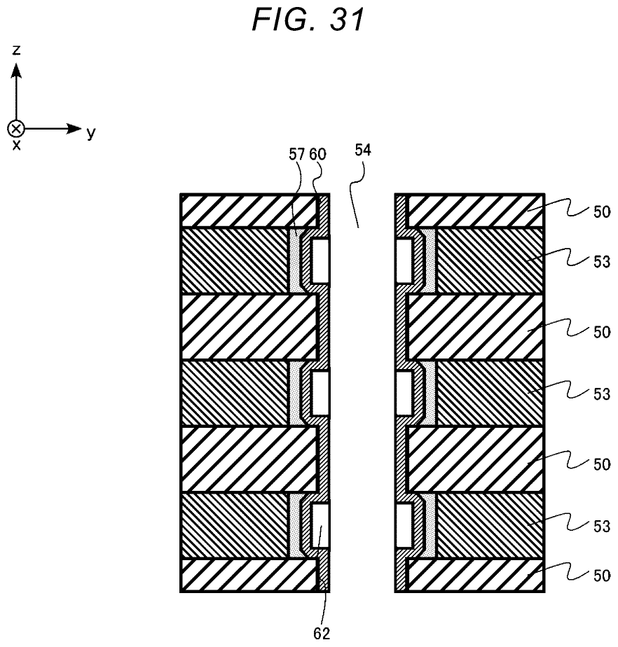

Next, the hafnium oxide film 62 of the inner surface of the opening 54 is removed by etching (FIG. 31). The hafnium oxide film 62 is removed, for example, using a RIE method. A part of the hafnium oxide film 62 remains in the recess portion formed by retracting the silicon nitride layer 53.

Next, the second silicon oxide film 64 is formed on an inner surface of the opening 54. The second silicon oxide film 64 is formed, for example, using a CVD method. The second silicon oxide film 64 is finally the first interface insulating layer 14.

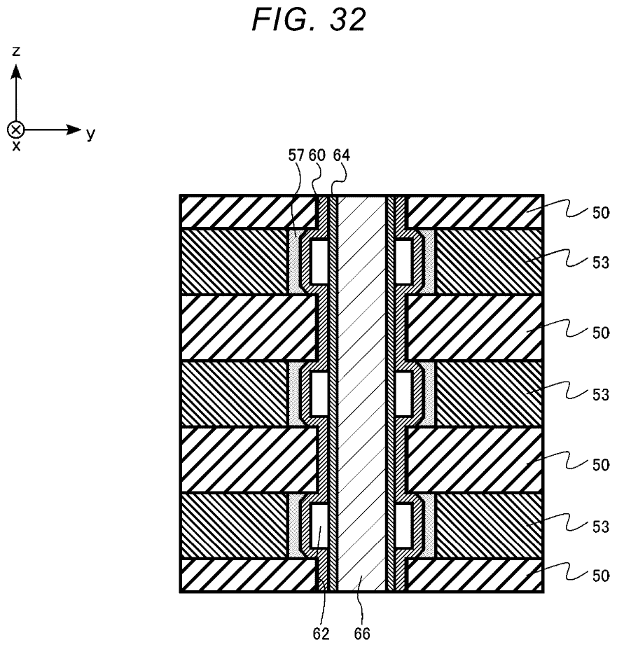

Next, the polycrystalline silicon film 66 is formed in the opening 54 to fill the opening 54 (FIG. 32). The polycrystalline silicon film 66 is formed, for example, using a CVD method. The polycrystalline silicon film 66 is finally the semiconductor layer 10.

Next, by performing a heat treatment, the hafnium oxide film 62 is crystallized. The heat treatment is so-called crystallized annealing. By crystallizing the hafnium oxide film 62, an orthorhombic or trigonal first crystal is formed in the hafnium oxide film 62. The heat treatment is performed, for example, in an inert gas atmosphere at a temperature of 800° C. or higher and 1000° C. or lower.

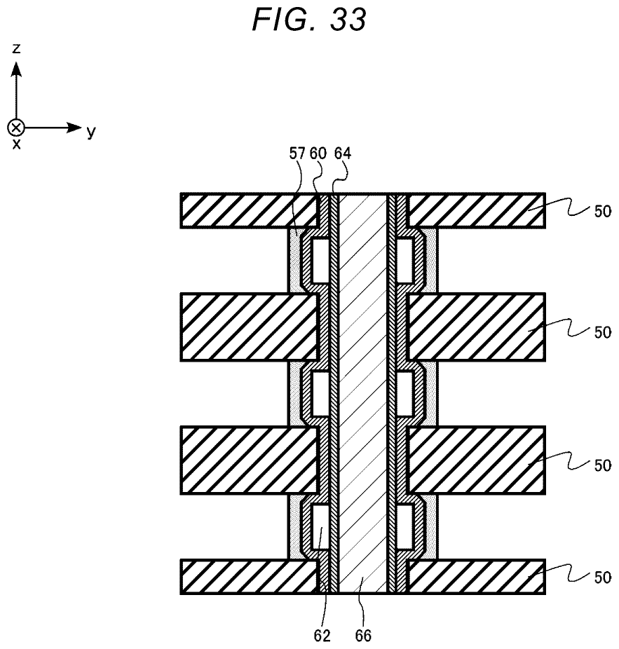

Next, using a groove for etching (not illustrated), the silicon nitride layer 53 is selectively removed by wet etching (FIG. 33).

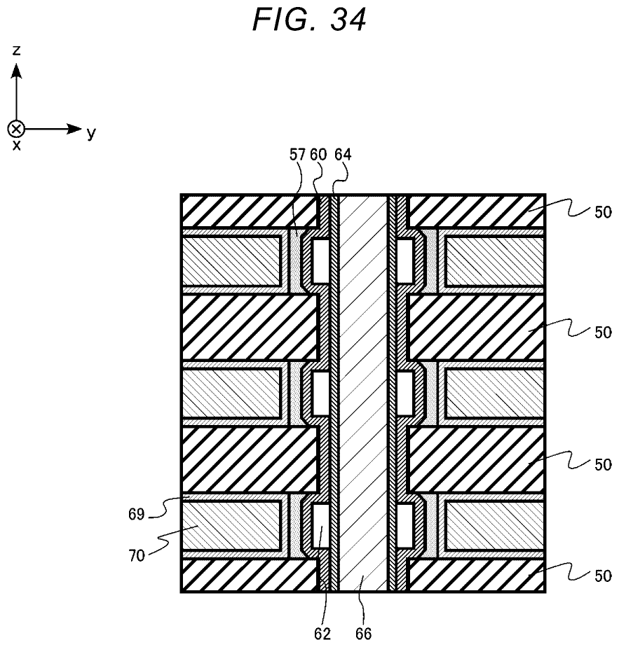

Next, a second titanium nitride film 69 and the tungsten film 70 are formed on the first titanium nitride film 57 (FIG. 34). The second titanium nitride film 69 and the tungsten film 70 are formed, for example, using a CVD method. The second titanium nitride film 69 and the tungsten film 70 are finally word lines WL. The second titanium nitride film 69 is finally the barrier metal film 41. The tungsten film 70 is finally the metal region 42.

The heat treatment for crystallizing the hafnium oxide film 62 can also be performed, for example, immediately after forming the second silicon oxide film 64. The heat treatment for crystallizing the hafnium oxide film 62 is performed, for example, before the removal of the silicon nitride layer 53 after the formation of the second silicon oxide film 64.

Through the above-described manufacturing method, the semiconductor memory device according to the second embodiment is manufactured.

Next, the operation and effects of the semiconductor memory device according to the second embodiment will be described.

The semiconductor memory device according to the second embodiment includes the metal layer 15 between the word line WL and the gate insulating layer 12. In the method of manufacturing the semiconductor memory device according to the second embodiment, when crystallized annealing is performed, the hafnium oxide film 62 is interposed between the first titanium nitride film 57 and the polycrystalline silicon film 66. By performing crystallized annealing in a state where the hafnium oxide film 62 is interposed between the first titanium nitride film 57 and the polycrystalline silicon film 66, the formation of the ferroelectric in the hafnium oxide film 62 is promoted due to the same reason as that of the first embodiment.

In particular, when the hafnium oxide film 62 is interposed between the first titanium nitride film 57 and the polycrystalline silicon film 66, the formation of the ferroelectric in the hafnium oxide film 62 is further promoted due to the same reason as that of the first embodiment.

In the method of manufacturing the semiconductor memory device according to the second embodiment, the silicon nitride layer 53 is removed after crystallized annealing, and subsequently the second titanium nitride film 69 and the tungsten film 70 are formed. The first titanium nitride film 57 remains even after the silicon nitride layer 53 is removed. Therefore, a decrease of stress applied to the hafnium oxide film 62 after removing the silicon nitride layer 53 is reduced, and a decrease in the ferroelectric formed in the hafnium oxide film 62 is reduced.

In the semiconductor memory device according to the second embodiment, a first thickness (t1 in FIG. 23) in the y direction perpendicular to the z direction of both end portions of the metal layer 15 in the z direction is more than a second thickness (t2 in FIG. 23) in the y direction of an intermediate portion of the metal layer 15 in the z direction. Therefore, in the method of manufacturing the semiconductor memory device according to the second embodiment, the first titanium nitride film 57 has a shape covering corner portions of the hafnium oxide film 62 that is the gate insulating layer 12. The first titanium nitride film 57 has the shape covering the corner portions of the hafnium oxide film 62 such that stress applied to the hafnium oxide film 62 during crystallized annealing increases. Accordingly, the formation of the ferroelectric in the hafnium oxide film 62 is promoted. In addition, a decrease of stress applied to the hafnium oxide film 62 after removing the silicon nitride layer 53 is reduced, and a decrease in the ferroelectric in the hafnium oxide film 62 is reduced.

In the semiconductor memory device according to the second embodiment, by increasing the ferroelectricity of the gate insulating layer 12, deterioration in the write endurance of the memory cell is reduced, and for example, the reliability of the semiconductor memory device according to the second embodiment is improved. Accordingly, the characteristics of the semiconductor memory device according to the second embodiment are improved.

In addition, in the semiconductor memory device according to the second embodiment, by not providing the gate insulating layer 12 between the interlayer insulating layers 18 and the semiconductor layer 10, as compared to when the gate insulating layer 12 is provided between the interlayer insulating layers 18 and the semiconductor layer 10, for example, read characteristics of data of the memory cell are stable. The reason for this is considered to be that the read characteristics of data of the memory cell is not affected by the polarization state of the gate insulating layer 12 between the interlayer insulating layers 18 and the semiconductor layer 10.

From the above, in the semiconductor memory device according to the second embodiment, the memory cell includes the metal layer 15 as in the first embodiment such that the ferroelectricity of the gate insulating layer 12 increases. Accordingly, the semiconductor memory device having excellent characteristics can be implemented.

### Third Embodiment

A semiconductor memory device according to a third embodiment includes: a semiconductor layer extending in a first direction; a first gate electrode layer; a second gate electrode layer provided to be isolated from the first gate electrode layer in the first direction; a gate insulating layer provided between the first gate electrode layer and the semiconductor layer, including hafnium (Hf) and oxygen (O), and including an orthorhombic or trigonal first crystal; a first insulating layer provided between the first gate electrode layer and the second gate electrode layer; and a second insulating layer provided between the first gate electrode layer and the second gate electrode layer, provided between the first insulating layer and the gate insulating layer, having a different chemical composition from the first insulating layer, and including at least any one element of aluminum (Al) and tantalum (Ta) and oxygen (O).

The semiconductor memory device according to the third embodiment is a three-dimensional NAND flash memory including memory cells of the MFS structure.

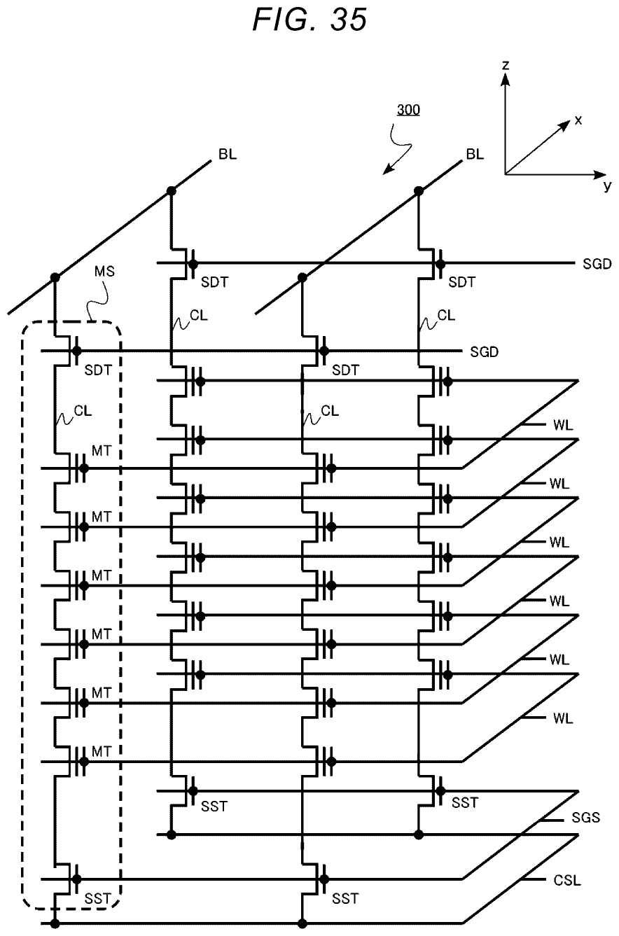

FIG. 35 is a circuit diagram illustrating a memory cell array of a semiconductor memory device according to a third embodiment.

As illustrated in FIG. 35, a memory cell array 300 of the three-dimensional NAND flash memory according to the third embodiment includes the plurality of word lines WL, the common source line CSL, the source select gate line SGS, the plurality of channel layers CL, the plurality of drain select gate lines SGD, the plurality of bit lines BL, and the plurality of memory strings MS.

A z direction in FIG. 35 is an example of the first direction. A y direction in FIG. 35 is an example of the second direction. An x direction in FIG. 35 is an example of the third direction. The first direction is a concept including the z direction and the opposite direction thereof. In addition, the second direction is a concept including the y direction and the opposite direction thereof. In addition, the third direction is a concept including the x direction and the opposite direction thereof.

The plurality of word lines WL are stacked in the z direction. The plurality of word lines WL are provided to be isolated in the z direction. The plurality of channel layers CL extend in the z direction. The plurality of bit lines BL extend in the x direction.

As illustrated in FIG. 35, the memory string MS is configured with the source select transistor SST, the plurality of memory cell transistors MT, and the drain select transistor SDT that are connected in series between the common source line CSL and the bit line BL. One memory string MS can be selected by the bit line BL and the drain select gate line SGD, and one memory cell transistor MT can be selected by the word line WL.

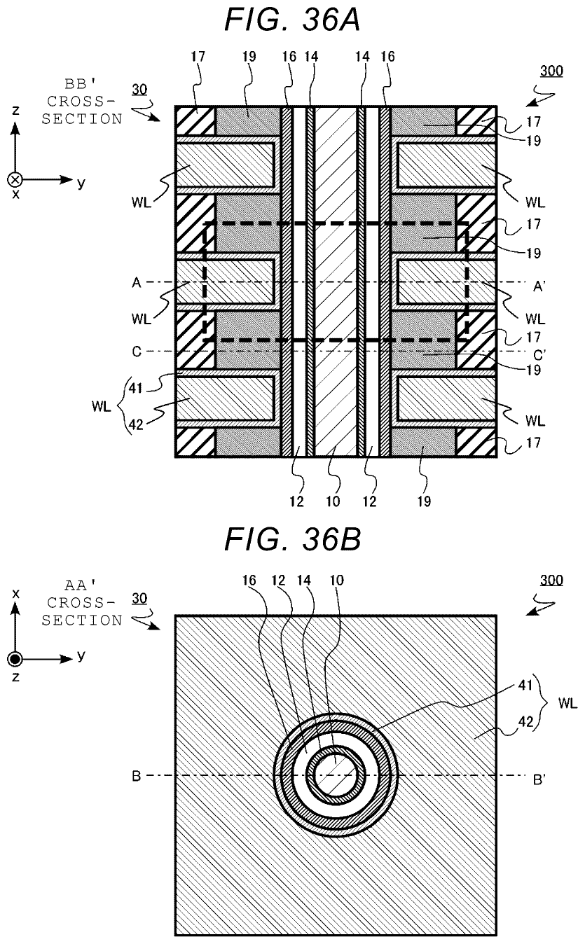

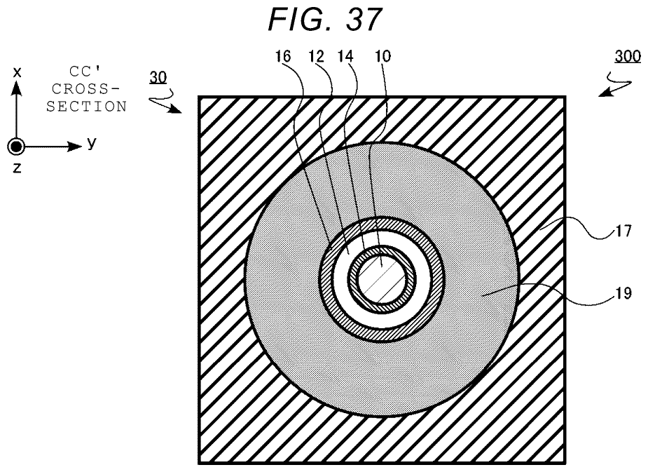

FIGS. 36A, 36B, and 37 are schematic cross-sectional views illustrating the memory cell array of the semiconductor memory device according to the third embodiment. FIGS. 36A, 36B, and 37 illustrate, for example, cross-sections of a plurality of memory cells of one memory string MS surrounded by dotted lines in the memory cell array 300 of FIG. 35.

FIG. 36A is a yz cross-sectional view of the memory cell array 300. FIG. 36A is a BB′ cross-section of FIG. 36B. FIG. 36B is a xy cross-sectional view of the memory cell array 300. FIG. 36B is an AA′ cross-section of FIG. 36A. FIG. 37 is a xy cross-sectional view of the memory cell array 300. FIG. 37 is a CC′ cross-sectional view of FIG. 36A. In FIG. 36A, a region surrounded by a broken line is one memory cell.

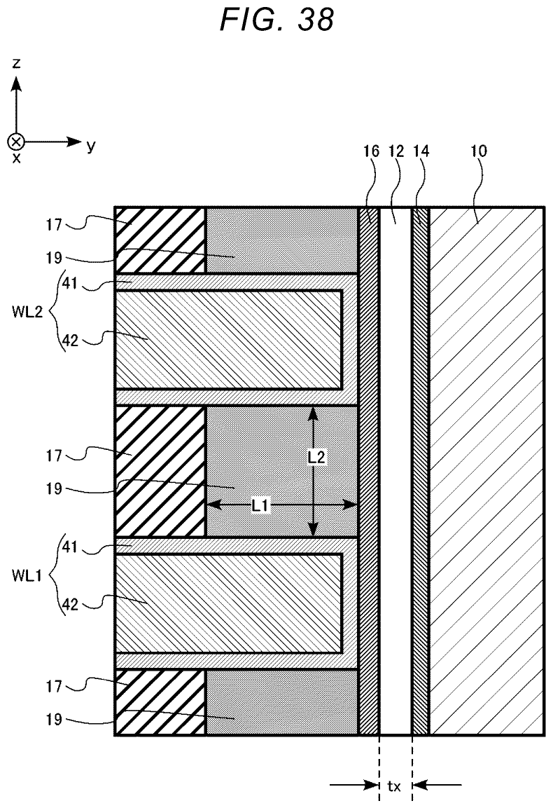

FIG. 38 is a schematic cross-sectional view illustrating memory cells of the semiconductor memory device according to the third embodiment. FIG. 38 is an enlarged cross-sectional view illustrating a part of two memory cells.

As illustrated in FIGS. 36A and 36B, the memory cell array 300 includes the plurality of word lines WL, the semiconductor layer 10, the gate insulating layer 12, the first interface insulating layer 14, the second interface insulating layer 16, a plurality of first interlayer insulating layers 17, and a plurality of second interlayer insulating layers 19. The plurality of word lines WL, the plurality of first interlayer insulating layers 17, and the plurality of second interlayer insulating layers 19 configure the stacked body 30. The word line WL includes the barrier metal film 41 and the metal region 42.

The first interlayer insulating layer 17 is an example of the first insulating layer. The second interlayer insulating layer 19 is an example of the second insulating layer. The barrier metal film 41 is an example of the conductive film.

As shown in FIG. 38, the two memory cells include the first word line WL1, the second word line WL2, the semiconductor layer 10, the gate insulating layer 12, the first interface insulating layer 14, the second interface insulating layer 16, a plurality of first interlayer insulating layers 17, and a plurality of second interlayer insulating layers 19.

The first word line WL1 is one of the plurality of word lines. The first word line WL1 is an example of the first gate electrode layer. The second word line WL2 is one of the plurality of word lines. The second word line WL2 is an example of the second gate electrode layer.

The word lines WL, the first interlayer insulating layers 17, and the second interlayer insulating layers 19 are provided on, for example, a semiconductor substrate (not illustrated). The word lines WL, the first interlayer insulating layers 17, and the second interlayer insulating layers 19 are provided in the z direction with respect to, for example, a semiconductor substrate (not illustrated).

The word line WL and the first interlayer insulating layer 17, and the word line WL and the second interlayer insulating layer 19 are alternately stacked in the z direction on the semiconductor substrate. The word lines WL are disposed to be isolated in the z direction. For example, the second word line WL2 is provided to be isolated from the first word line WL1 in the z direction. The plurality of word lines WL, the plurality of first interlayer insulating layers 17, and the plurality of second interlayer insulating layers 19 configure the stacked body 30.

The word line WL is a plate-shaped conductor. The word line WL is, for example, a metal, a metal nitride, a metal carbide, or a semiconductor. The word line WL includes, for example, the barrier metal film 41 and the metal region 42. The barrier metal film 41 is provided between the metal region 42 and the gate insulating layer 12.

The barrier metal film 41 includes, for example, a metal, a metal nitride, or a metal carbide. The barrier metal film 41 includes, for example, titanium nitride, tungsten nitride, or tantalum nitride. The barrier metal film 41 is, for example, a titanium nitride film.

The metal region 42 is a metal. The metal region 42 includes, for example, tungsten (W) or molybdenum (Mo). The metal region 42 is, for example, a tungsten layer or a molybdenum layer. The metal region 42 includes, for example, a different metal element from the barrier metal film 41.

The word line WL functions as a control electrode of the memory cell transistor MT.

A length of the word line WL in the z direction is, for example, 5 nm or more and 40 nm or less.

The first interlayer insulating layer 17 is provided between the word line WL and the word line WL. The first interlayer insulating layer 17 is provided between the first word line WL1 and the second word line WL2.

The first interlayer insulating layer 17 separates the word line WL and the word line WL. The first interlayer insulating layer 17 separates, for example, the first word line WL1 and the second word line WL2. The first interlayer insulating layer 17 is, for example, an oxide, oxynitride, or nitride. The first interlayer insulating layer 17 includes, for example, silicon (Si) and oxygen (O). The first interlayer insulating layer 17 is, for example, silicon oxide.

A length of the first interlayer insulating layer 17 in the z direction is, for example, 5 nm or more and 40 nm or less.

The second interlayer insulating layer 19 is provided between the word line WL and the word line WL. The second interlayer insulating layer 19 is provided between the first word line WL1 and the second word line WL2. The second interlayer insulating layer 19 is in contact with, for example, the word line WL in the z direction. The second interlayer insulating layer 19 is in contact with, for example, the first word line WL1 and the second word line WL2 in the z direction.

The second interlayer insulating layer 19 separates the word line WL and the word line WL. The second interlayer insulating layer 19 separates, for example, the first word line WL1 and the second word line WL2.

The second interlayer insulating layer 19 is provided between the first interlayer insulating layer 17 and the semiconductor layer 10. The second interlayer insulating layer 19 is in contact with, for example, the first interlayer insulating layer 17. The second interlayer insulating layer 19 is provided, for example, between the first interlayer insulating layer 17 and the second interface insulating layer 16. The second interlayer insulating layer 19 is in contact with, for example, the second interface insulating layer 16.

As illustrated in FIG. 37, the second interlayer insulating layer 19 surrounds the semiconductor layer 10 in a cross-section perpendicular to the z direction. As illustrated in FIG. 37, the second interlayer insulating layer 19 surrounds the gate insulating layer 12 in a cross-section perpendicular to the z direction.

The second interlayer insulating layer 19 is an insulator. A chemical composition of the second interlayer insulating layer 19 is different from a chemical composition of the first interlayer insulating layer 17. The second interlayer insulating layer 19 includes at least any one element of aluminum (Al) and tantalum (Ta) and oxygen (O). The second interlayer insulating layer 19 includes, for example, aluminum oxide or tantalum oxide. The second interlayer insulating layer 19 is, for example, aluminum oxide or tantalum oxide.

A density of amorphous aluminum oxide is lower than a density of crystalline aluminum oxide. When the amorphous aluminum oxide is crystallized, the volume of aluminum oxide is about 81%. When the amorphous aluminum oxide is crystallized, the volume of aluminum oxide decreases.

A density of amorphous tantalum oxide is lower than a density of crystalline tantalum oxide. When the amorphous tantalum oxide is crystallized, the volume of tantalum oxide is about 89%. When the amorphous tantalum oxide is crystallized, the volume of tantalum oxide decreases.

A crystallization temperature of a material in the second interlayer insulating layer 19 is lower than, for example, a crystallization temperature of a material in the first interlayer insulating layer 17. The crystallization temperatures of aluminum oxide and tantalum oxide are lower than, for example, a crystallization temperature of the silicon oxide.

A length of the second interlayer insulating layer 19 in the z direction is, for example, 5 nm or more and 40 nm or less.

A first length (L1 in FIG. 38) of the second interlayer insulating layer 19 in the y direction is more than, for example, a thickness (tx in FIG. 38) of the gate insulating layer 12 in the y direction. The first length (L1 in FIG. 38) of the second interlayer insulating layer 19 in the y direction is more than, for example, a first length (L2 in FIG. 38) of the second interlayer insulating layer 19 in the z direction.

The semiconductor layer 10 is provided in the stacked body 30. The semiconductor layer 10 extends in the z direction. The semiconductor layer 10 is provided to penetrate the stacked body 30. The semiconductor layer 10 is, for example, columnar or cylindrical. The semiconductor layer 10 corresponds to the channel layers CL. For example, an insulating film may be provided inside the cylindrical semiconductor layer 10. The insulating film is, for example, silicon oxide.

The semiconductor layer 10 is, for example, a polycrystalline semiconductor. The semiconductor layer 10 is, for example, polycrystalline silicon. The semiconductor layer 10 functions as a channel of the memory cell transistor MT.

The gate insulating layer 12 is provided between the word line WL and the semiconductor layer 10. The gate insulating layer 12 is provided between the first word line WL1 and the semiconductor layer 10. The gate insulating layer 12 is provided between the second word line WL2 and the semiconductor layer 10.

The gate insulating layer 12 is provided between the first interlayer insulating layer 17 and the semiconductor layer 10. The gate insulating layer 12 is provided between the second interlayer insulating layer 19 and the semiconductor layer 10.

The gate insulating layer 12 includes hafnium (Hf) and oxygen (O). For example, an atomic concentration of hafnium (Hf) is the highest among atomic concentrations of elements other than oxygen (O) in the gate insulating layer 12. A ratio of the atomic concentration of hafnium (Hf) to the sum of the atomic concentrations of the elements other than oxygen (O) in the gate insulating layer 12 is, for example, 90% or more.

The gate insulating layer 12 includes hafnium oxide. The gate insulating layer 12 includes, for example, hafnium oxide as a major component. The gate insulating layer 12 including hafnium oxide as a major component represents that a molar fraction of hafnium oxide is the highest among molar fractions of substances in the gate insulating layer 12. The molar fraction of hafnium oxide in the gate insulating layer 12 is, for example, 90% or higher.

The gate insulating layer 12 includes a ferroelectric. The gate insulating layer 12 is, for example, a ferroelectric layer. The gate insulating layer 12 is crystalline.

The gate insulating layer 12 includes an orthorhombic or trigonal first crystal. The first crystal is hafnium oxide. When hafnium oxide is an orthorhombic or trigonal crystal, the hafnium oxide has ferroelectricity. When hafnium oxide is an orthorhombic or trigonal crystal, the hafnium oxide is a ferroelectric. The first crystal is a ferroelectric.

When hafnium oxide is, for example, an orthorhombic III crystal (space group Pbc2₁, space group No. 29) or a trigonal crystal (space group R3m, P3, or R3, space group No. 160, 143, or 146), the hafnium oxide has ferroelectricity.

When hafnium oxide is a crystal other than an orthorhombic or trigonal crystal or is amorphous, the hafnium oxide does not have ferroelectricity. When hafnium oxide is a crystal other than an orthorhombic or trigonal crystal or is amorphous, the hafnium oxide is a paraelectric. The crystal other than an orthorhombic or trigonal crystal refers to a cubic, hexagonal, tetragonal, monoclinic, or triclinic crystal.

The gate insulating layer 12 includes, for example, cubic, hexagonal, tetragonal, monoclinic, or triclinic second crystal. The second crystal is a paraelectric.

The gate insulating layer 12 includes, for example, the orthorhombic or trigonal first crystal as a main component. Including the orthorhombic or trigonal first crystal as a main component refers to that the orthorhombic or trigonal first crystal has the highest abundance among substances forming the gate insulating layer 12. In other words, including the orthorhombic or trigonal first crystal as a main component means that there is no substance having a higher abundance than the orthorhombic or trigonal first crystal among the substances forming the gate insulating layer 12. For example, an abundance of the first crystal in the ferroelectric is higher than that of the second crystal in the paraelectric among the substances forming the gate insulating layer 12. In other words, for example, the abundance of the first crystal in the ferroelectric is the highest among the crystals forming the gate insulating layer 12.

The gate insulating layer 12 includes, for example, a ferroelectric as a main component. The abundance of the ferroelectric in the gate insulating layer 12 is higher than, for example, the abundance of the paraelectric in the gate insulating layer 12.

For example, an abundance of the first crystal in crystals in the gate insulating layer 12 provided between the second interlayer insulating layer 19 and the semiconductor layer 10 is less than an abundance of the first crystal in crystals in the gate insulating layer 12 provided between the first word line WL1 and the semiconductor layer 10. For example, an abundance of the first crystal with respect to the second crystal in the gate insulating layer 12 provided between the second interlayer insulating layer 19 and the semiconductor layer 10 is less than an abundance of the first crystal with respect to the second crystal in the gate insulating layer 12 provided between the first word line WL1 and the semiconductor layer 10. For example, an abundance of the ferroelectric in substances in the gate insulating layer 12 provided between the second interlayer insulating layer 19 and the semiconductor layer 10 is less than an abundance of the ferroelectric in substances in the gate insulating layer 12 provided between the first word line WL1 and the semiconductor layer 10.

The gate insulating layer 12 includes, for example, at least one addition element selected from the group consisting of silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Ru). Hafnium oxide in the gate insulating layer 12 includes the addition element. For example, hafnium oxide includes the addition element such that the hafnium oxide is likely to exhibit ferroelectricity.

The first interface insulating layer 14 is provided between the first word line WL1 and the semiconductor layer 10. The first interface insulating layer 14 is provided between the second word line WL2 and the semiconductor layer 10. The first interface insulating layer 14 is provided between the gate insulating layer 12 and the semiconductor layer 10. The first interface insulating layer 14 is provided between the second interlayer insulating layer 19 and the semiconductor layer 10.

A material of the first interface insulating layer 14 is different from, for example, a material of the gate insulating layer 12. The first interface insulating layer 14 is, for example, an oxide, oxynitride, or nitride. The first interface insulating layer 14 is, for example, silicon oxide.

A structure where the first interface insulating layer 14 is not provided and the gate insulating layer 12 is in direct contact with the semiconductor layer can also be adopted.

The second interface insulating layer 16 is provided between the first word line WL1 and the gate insulating layer 12. The second interface insulating layer 16 is provided between the second word line WL2 and the gate insulating layer 12. The second interface insulating layer 16 is provided between the second interlayer insulating layer 19 and the semiconductor layer 10.

A material of the second interface insulating layer 16 is different from, for example, the material of the gate insulating layer 12. The second interface insulating layer 16 is, for example, an oxide, oxynitride, or nitride. The second interface insulating layer 16 is, for example, silicon oxide or aluminum oxide.

A structure where the second interface insulating layer 16 is not provided and the gate insulating layer 12 is in direct contact with the word line WL can also be adopted.

In the memory cell according to the third embodiment, for example, a polarization reversal state of the ferroelectric in the gate insulating layer 12 is controlled by a voltage to be applied between the first word line WL1 and the semiconductor layer 10. A threshold voltage of the memory cell transistor MT changes depending on the polarization reversal state of the gate insulating layer 12. By changing the threshold voltage of the memory cell transistor MT, an ON current of the memory cell transistor MT changes. For example, when a state where the threshold voltage is high and the ON current is low is defined by data of “0” and a state where the threshold voltage is low and the ON current is high is defined by data of “1”, the memory cell can store one-bit data of “0” and “1”.

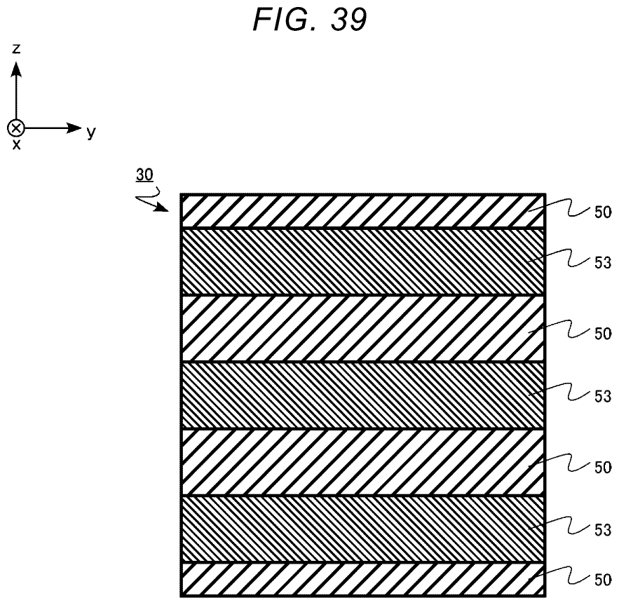

Next, an example of a method of manufacturing the semiconductor memory device according to the third embodiment will be described. FIGS. 39, 40, 41, 42, 43, 44, 45, 46, 47, and 48 are schematic cross-sectional views illustrating the method of manufacturing the semiconductor memory device according to the third embodiment. Each of FIGS. 39 to 48 illustrates cross-sections corresponding to FIG. 36A. FIGS. 39 to 48 illustrate the example of the method of manufacturing the memory cell array 300 of the semiconductor memory device.

First, the silicon oxide layer 50 and the silicon nitride layer 53 are alternately stacked on a semiconductor substrate (not illustrated) (FIG. 39). The stacked body 30 is formed with the silicon oxide layer 50 and the silicon nitride layer 53. The silicon oxide layer 50 and the silicon nitride layer 53 are formed, for example, using a CVD method. A part of the silicon oxide layer 50 is finally the first interlayer insulating layer 17. The silicon oxide layer 50 is amorphous.

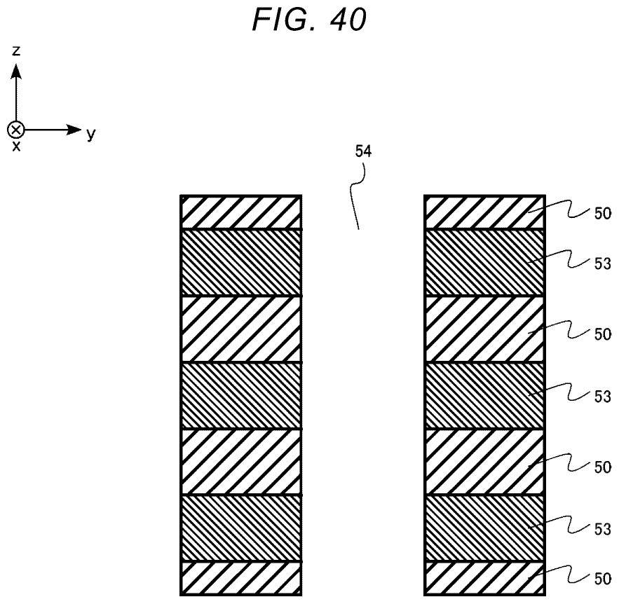

Next, the opening 54 is formed in the silicon oxide layer 50 and the silicon nitride layer 53 (FIG. 40). The opening 54 is formed, for example, using a lithography method and a RIE method.

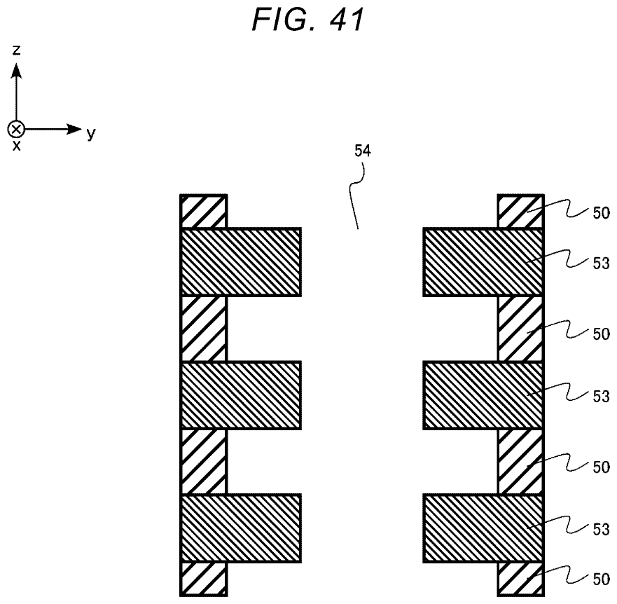

Next, the silicon oxide layer 50 exposed to the inner surface of the opening 54 is selectively retracted by wet etching (FIG. 41). During the wet etching, for example, the silicon oxide layer 50 is selectively etched relative to the silicon nitride layer 53 using a buffered hydrofluoric acid solution. The silicon oxide layer 50 on the inner surface of the opening 54 is retracted to form a recess portion.

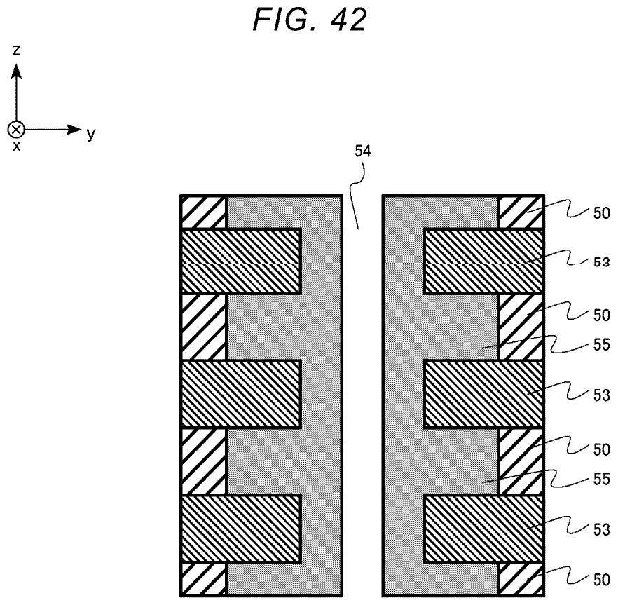

Next, an aluminum oxide film 55 is formed in the opening 54 (FIG. 42). The aluminum oxide film 55 is formed, for example, using a CVD method. The aluminum oxide film 55 is amorphous. The aluminum oxide film 55 is formed on the inner surface of the opening 54 and the recess portion of the opening 54. A part of the aluminum oxide film 55 is finally the second interlayer insulating layer 19.

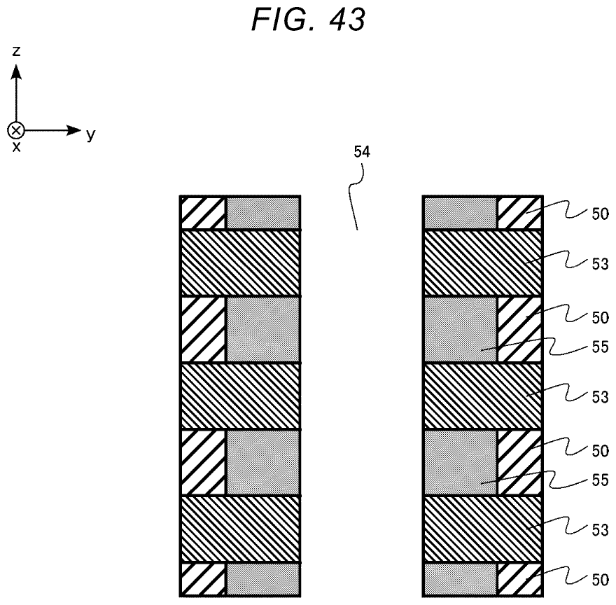

Next, the aluminum oxide film 55 of the inner surface of the opening 54 is removed by etching (FIG. 43). The aluminum oxide film 55 is removed using a RIE method or a wet etching method. A part of the aluminum oxide film 55 remains in the recess portion formed by retracting the silicon oxide layer 50.

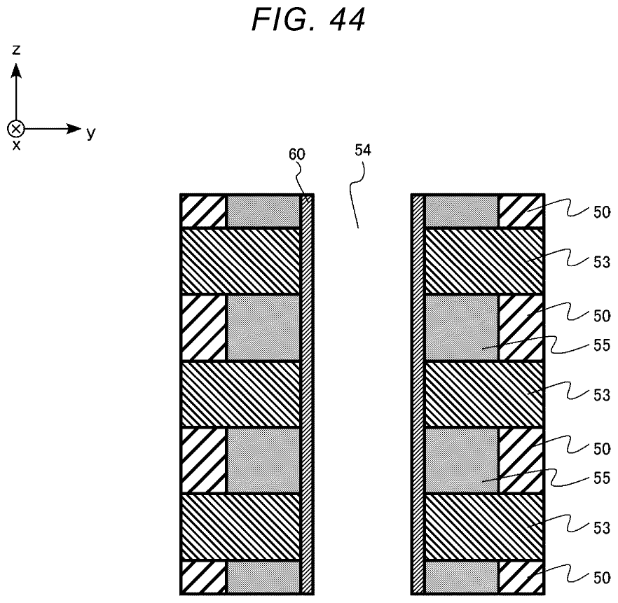

Next, the first silicon oxide film 60 is formed in the opening 54 (FIG. 44). The first silicon oxide film 60 is formed, for example, using a CVD method. The first silicon oxide film 60 is finally the second interface insulating layer 16.

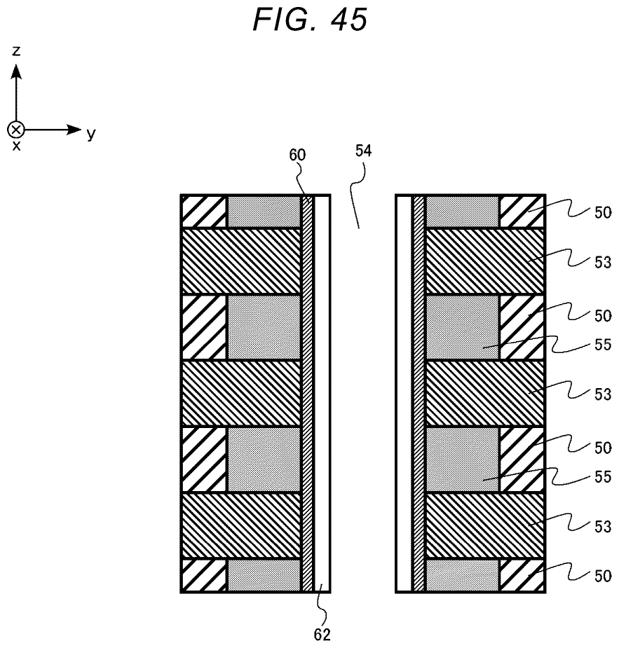

Next, the hafnium oxide film 62 is formed in the opening 54 (FIG. 45). The hafnium oxide film 62 is formed, for example, using an ALD method. For example, silicon (Si) as an addition element is added to the hafnium oxide film 62. The hafnium oxide film 62 is finally the gate insulating layer 12.

Next, the second silicon oxide film 64 is formed on the inner surface of the opening 54. The second silicon oxide film 64 is formed, for example, using a CVD method. The second silicon oxide film 64 is finally the first interface insulating layer 14.

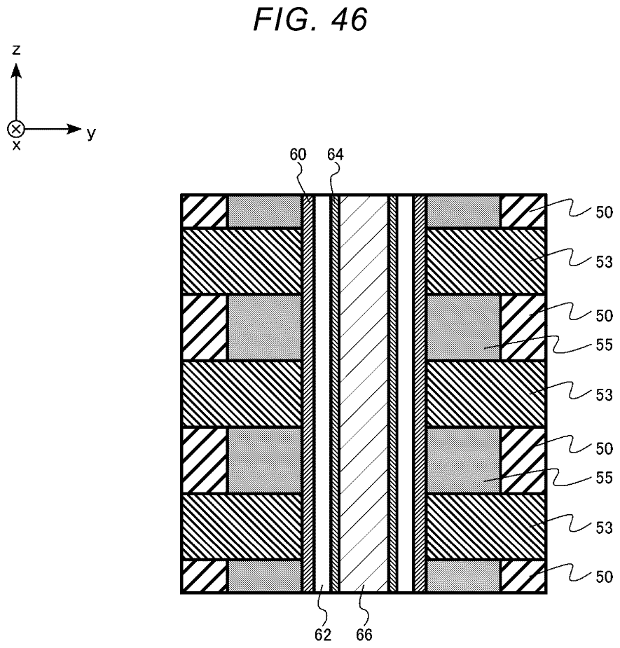

Next, the polycrystalline silicon film 66 is formed in the opening 54 to fill the opening 54 (FIG. 46). The polycrystalline silicon film 66 is formed, for example, using a CVD method. The polycrystalline silicon film 66 is finally the semiconductor layer 10.

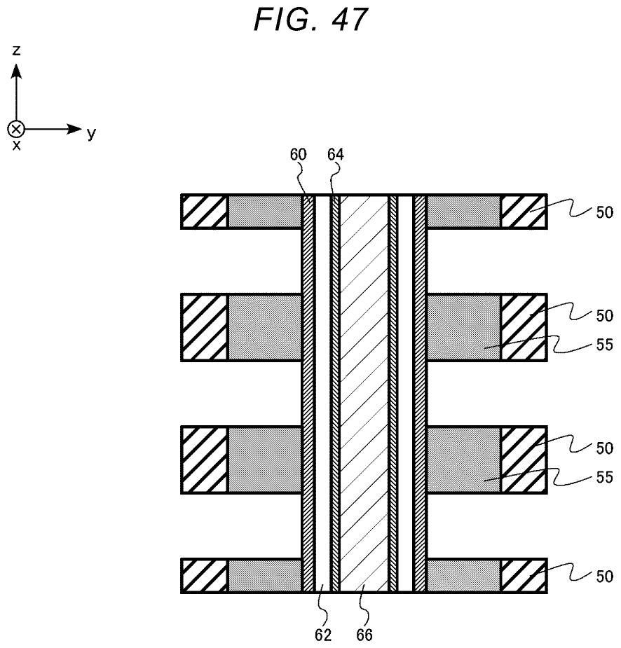

Next, using a groove for etching (not illustrated), the silicon nitride layer 53 is selectively removed by wet etching (FIG. 47).

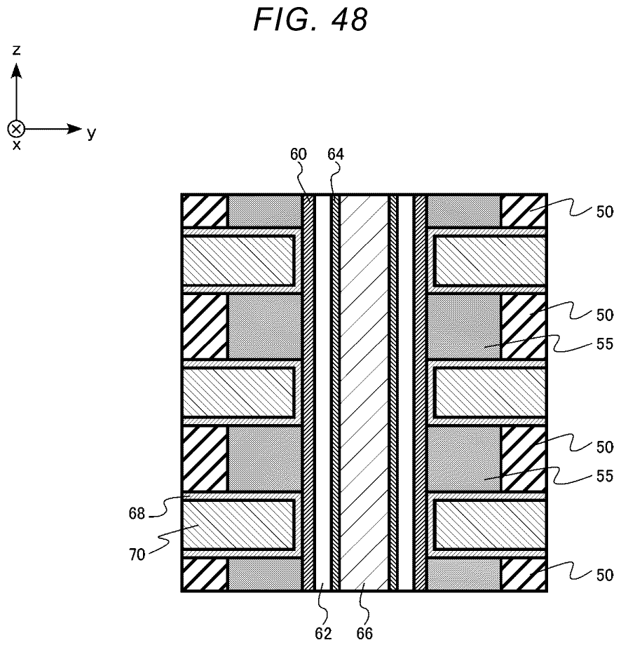

Next, the titanium nitride film 68 and the tungsten film 70 are formed on the first silicon oxide film 60 (FIG. 48). The titanium nitride film 68 and the tungsten film 70 are formed, for example, using a CVD method. The titanium nitride film 68 and the tungsten film 70 are finally word lines WL. The titanium nitride film 68 is finally the barrier metal film 41. The tungsten film 70 is finally the metal region 42.

Next, by performing a heat treatment, the hafnium oxide film 62 is crystallized. The heat treatment is so-called crystallized annealing. By crystallizing the hafnium oxide film 62, an orthorhombic or trigonal first crystal is formed in the hafnium oxide film 62. The heat treatment is performed, for example, in an inert gas atmosphere at a temperature of 800° C. or higher and 1000° C. or lower.

Through the heat treatment, the amorphous aluminum oxide film 55 is also crystallized. When the amorphous aluminum oxide film 55 is crystallized, the volume of the aluminum oxide film 55 decreases. Through the heat treatment, the amorphous silicon oxide layer 50 is not crystallized.

Through the above-described manufacturing method, the semiconductor memory device according to the third embodiment is manufactured.

Next, the operation and effects of the semiconductor memory device according to the third embodiment will be described.

In the method of manufacturing the semiconductor memory device according to the third embodiment, by performing crystallized annealing on the hafnium oxide film 62, the hafnium oxide film 62 is crystallized. By crystallizing the hafnium oxide film 62, an orthorhombic or trigonal first crystal is formed in the hafnium oxide film 62. In other words, a ferroelectric is formed in the hafnium oxide film 62.

The formation of the ferroelectric in the hafnium oxide film 62 is promoted by stress applied to the hafnium oxide film 62 during the crystallized annealing. During the crystallized annealing, when tensile stress is applied to the hafnium oxide film 62, the formation of the ferroelectric is promoted. On the other hand, during the crystallized annealing, when compressive stress is applied to the hafnium oxide film 62, the formation of the ferroelectric is prevented.

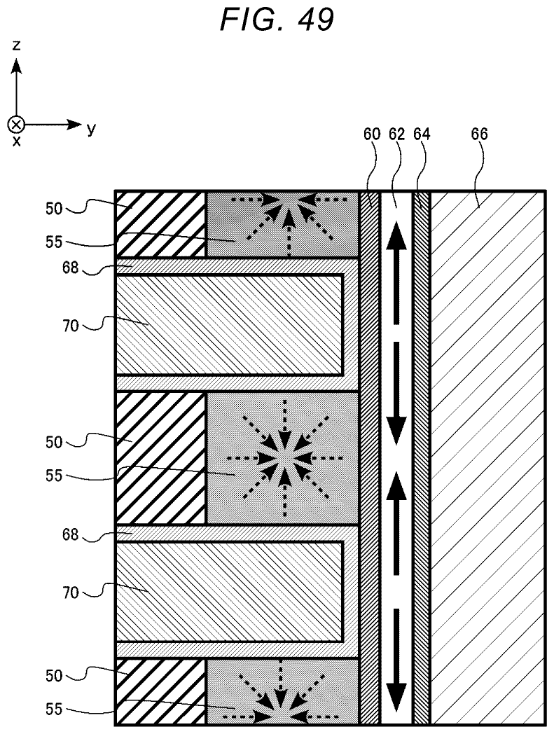

FIG. 49 is a diagram illustrating the operation and effects of the semiconductor memory device according to the third embodiment. FIG. 49 is a diagram illustrating the stress applied to the hafnium oxide film 62 during the crystallized annealing. FIG. 49 is an enlarged view corresponding to FIG. 48.

During the crystallized annealing, the amorphous aluminum oxide film 55 is crystallized as indicated by a dotted line arrow in FIG. 49 such that the volume decreases. Accordingly, as indicated by a solid line arrow in FIG. 49, tensile stress is applied to the hafnium oxide film 62 between the titanium nitride film 68 and the tungsten film 70 that are the word lines WL and the polycrystalline silicon film 66 that is the semiconductor layer 10. On the other hand, compressive stress is applied to the hafnium oxide film 62 between the aluminum oxide film 55 that is the second interlayer insulating layer 19 and the polycrystalline silicon film 66.

In the portion of the hafnium oxide film 62 where the tensile stress is applied, the formation of the ferroelectric is promoted. Accordingly, the ferroelectricity of the gate insulating layer 12 between the word line WL and the semiconductor layer 10 increases. On the other hand, in the portion of the hafnium oxide film 62 where the compressive stress is applied, the formation of the ferroelectric is prevented. Accordingly, the ferroelectricity of the gate insulating layer 12 between the second interlayer insulating layer 19 and the semiconductor layer 10 decreases.

By increasing the ferroelectricity of the gate insulating layer 12 between the word line WL and the semiconductor layer 10, for example, the write endurance of the memory cell is improved, and the reliability of the semiconductor memory device according to the third embodiment is improved. Accordingly, the characteristics of the semiconductor memory device according to the third embodiment are improved.

Further, in the semiconductor memory device according to the third embodiment, the ferroelectricity of the gate insulating layer 12 between the second interlayer insulating layer 19 and the semiconductor layer 10 decreases. In other words, the ferroelectricity of the gate insulating layer 12 positioned between two word lines WL that are vertically adjacent to each other decreases. Accordingly, for example, the read characteristics of data of the memory cell are stable. The reason for this is that the read characteristics of data of the memory cell is not likely to be affected by the polarization state of the gate insulating layer 12 positioned between the word lines WL.

From the viewpoint of increasing the ferroelectricity of the gate insulating layer 12, it is preferable that the first length (L1 in FIG. 38) of the second interlayer insulating layer 19 in the y direction is more than the thickness (tx in FIG. 38) of the gate insulating layer 12 in the y direction. In addition, from the viewpoint of increasing the ferroelectricity of the gate insulating layer 12, It is preferable that the first length (L1 in FIG. 38) of the second interlayer insulating layer 19 in the y direction is more than the first length (L2 in FIG. 38) of the second interlayer insulating layer 19 in the z direction. By increasing the volume of the second interlayer insulating layer 19, the stress applied to the hafnium oxide film 62 during the crystallized annealing increases.

From the above, in the semiconductor memory device according to the third embodiment, the memory cell includes the second interlayer insulating layer 19 such that the ferroelectricity of the gate insulating layer 12 increases. Accordingly, the semiconductor memory device having excellent characteristics can be implemented.

In the first to third embodiments, the example where the word line WL is a plate-shaped conductor and the semiconductor layer 10 is surrounded by the word line WL will be described. However, for example, the word line WL can also have a linear shape extending in the y direction, and a memory cell array structure where a part of the semiconductor layer 10 and the word line WL face each other can also be adopted. An insulating layer extending in the z direction may be provided in the semiconductor layer 10, and a structure where the insulating layer is surrounded by the semiconductor layer 10 may be adopted. As a material of the insulating layer, for example, silicon oxide is used.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. For example, a component of one embodiment may be replaced with a component of another embodiment or changed. The accompanying claims and their equivalents are intended to cover such forms or modifications as would fall within the scope and spirit of the disclosure.

What is claimed is:

1. A semiconductor memory device comprising:
a semiconductor layer extending in a first direction;
a first gate electrode layer;
a second gate electrode layer provided spaced from the first gate electrode layer in the first direction;
a gate insulating layer provided between the first gate electrode layer and the semiconductor layer, including hafnium (Hf) and oxygen (O), and including an orthorhombic or trigonal first crystal; and
a metal silicide layer provided between the first gate electrode layer and the gate insulating layer.

2. The semiconductor memory device according to claim 1, further comprising a first insulating layer provided between the first gate electrode layer and the second gate electrode layer,
wherein the metal silicide layer is not provided between the first gate electrode layer and the first insulating layer.

3. The semiconductor memory device according to claim 2,
wherein the metal silicide layer is not provided between the first insulating layer and the semiconductor layer.

4. The semiconductor memory device according to claim 2,
wherein the gate insulating layer is not provided between the first insulating layer and the semiconductor layer.

5. The semiconductor memory device according to claim 1,
wherein the first gate electrode layer and the metal silicide layer include different metal elements.

6. The semiconductor memory device according to claim 1,
wherein the metal silicide layer surrounds the gate insulating layer.

7. The semiconductor memory device according to claim 1,
wherein the metal silicide layer includes titanium silicide or tungsten silicide.

8. The semiconductor memory device according to claim 2,
wherein the first gate electrode layer includes a metal region, a conductive film between the metal region and the metal silicide layer, and a conductive film between the metal region and the first insulating layer.

9. The semiconductor memory device according to claim 2,
wherein the gate insulating layer includes a ferroelectric.

10. The semiconductor memory device according to claim 1,
wherein the gate insulating layer includes at least one element selected from the group consisting of silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Ru).

11. A semiconductor memory device comprising:
a semiconductor layer extending in a first direction;
a first gate electrode layer;
a second gate electrode layer spaced from the first gate electrode layer in the first direction;
a first insulating layer provided between the first gate electrode layer and the second gate electrode layer;
a gate insulating layer provided between the first gate electrode layer and the semiconductor layer, including hafnium (Hf) and oxygen (O), and including an orthorhombic or trigonal first crystal; and
a metal layer provided between the first gate electrode layer and the gate insulating layer,
wherein the gate insulating layer is not provided between the first insulating layer and the semiconductor layer in a second direction perpendicular to the first direction, and
a first thickness in the second direction of both end portions of the metal layer in the first direction is greater than a second thickness in the second direction of an intermediate portion of the metal layer in the first direction.

12. The semiconductor memory device according to claim 11,
wherein a first distance in the second direction between both of the end portions and the semiconductor layer is less than a second distance in the second direction between the intermediate portion and the semiconductor layer.

13. The semiconductor memory device according to claim 11,
wherein the metal layer is not provided between the first gate electrode layer and the first insulating layer.

14. The semiconductor memory device according to claim 11,
wherein the first gate electrode layer includes a metal element different from the metal layer.

15. The semiconductor memory device according to claim 11,
wherein the metal layer surrounds the gate insulating layer.

16. The semiconductor memory device according to claim 11,
wherein the metal layer surrounds the semiconductor layer.

17. The semiconductor memory device according to claim 11,
wherein the metal layer includes titanium (Ti) or tungsten (W).

18. The semiconductor memory device according to claim 11,
wherein the first gate electrode layer includes a metal region, a conductive film between the metal region and the metal layer, and a conductive film between the metal region and the first insulating layer.

19. The semiconductor memory device according to claim 12,
wherein the gate insulating layer includes a ferroelectric.

20. The semiconductor memory device according to claim 11,
wherein the gate insulating layer includes at least one element selected from the group consisting of silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Ru).

21. A semiconductor memory device comprising:
a semiconductor layer extending in a first direction;
a first gate electrode layer;
a second gate electrode layer spaced from the first gate electrode layer in the first direction;
a gate insulating layer provided between the first gate electrode layer and the semiconductor layer, including hafnium (Hf) and oxygen (O), and including an orthorhombic or trigonal first crystal;
a first insulating layer provided between the first gate electrode layer and the second gate electrode layer; and
a second insulating layer provided between the first gate electrode layer and the second gate electrode layer, provided between the first insulating layer and the gate insulating layer, having a different chemical composition from the first insulating layer, and including at least any one element of aluminum (Al) and tantalum (Ta) and oxygen (O).

22. The semiconductor memory device according to claim 21,
wherein the first insulating layer includes silicon (Si) and oxygen (O).

23. The semiconductor memory device according to claim 21,
wherein an abundance of the first crystal in crystals in the gate insulating layer provided between the second insulating layer and the semiconductor layer is less than an abundance of the first crystal in crystals in the gate insulating layer provided between the first gate electrode layer and the semiconductor layer.

24. The semiconductor memory device according to claim 21,
wherein a first length of the second insulating layer in a second direction perpendicular to the first direction is greater than a thickness of the gate insulating layer in the second direction.

25. The semiconductor memory device according to claim 21,
wherein a first length of the second insulating layer in a second direction perpendicular to the first direction is greater than a second length of the second insulating layer in the first direction.

26. The semiconductor memory device according to claim 21,
wherein the second insulating layer surrounds the gate insulating layer.

27. The semiconductor memory device according to claim 21,
wherein the gate insulating layer includes a ferroelectric.

28. The semiconductor memory device according to claim 21,
wherein the gate insulating layer includes at least one element selected from the group consisting of silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Ru).
